(19) United States
(12) Patent Application Publication
(10) Pub. No.: US 2022/0300438 A1
(43) Pub. Date: Sep. 22, 2022

(54) SEMICONDUCTOR MEMORY DEVICE AND MEMORY SYSTEM

(71) Applicant: Kioxia Corporation, Tokyo (JP)

(72) Inventors: Goichi OOTOMO, Kawasaki Kanagawa (JP); Katsuki MATSUDERA, Kawasaki Kanagawa (JP)

(73) Assignee: Kioxia Corporation, Tokyo (JP)

(21) Appl. No.: 17/470,427

(22) Filed: Sep. 9, 2021

(30) Foreign Application Priority Data
Mar. 22, 2021 (JP) 2021-047485

(51) Int. Cl. G06F 13/16

(52) U.S. Cl. CPC G06F 13/1678

(57) ABSTRACT

A semiconductor memory device includes a plurality of first chips and a second chip. The second chip is connected to the first chips via M second channels. Upon receipt of first data via the first channel at a transfer rate N times higher than the transfer rate per a single second channel, the second chip transmits the first data to the N first chips in parallel via the N second channels by sorting the first data into N pieces in a unit of bus width of the first channel. Upon receipt of L pieces of third data in parallel from L of the M second channels, the second chip sequentially concatenates the L pieces of third data in a unit of bus width of the first channel and transmits the data via the first channel at the transfer rate L times higher the transfer rate per the single second channel.

### CROSS-REFERENCE TO RELATED APPLICATIONS

This application is based upon and claims the benefit of priority from Japanese Patent Application No. 2021-047485, filed on Mar. 22, 2021; the entire contents of which are incorporated herein by reference.

### FIELD

Embodiments described herein relate generally to a semiconductor memory device and a memory system.

### BACKGROUND

Semiconductor storage devices are available, which include a plurality of memory chips, an external terminal group connectable to a host, and a semiconductor integrated circuit called a bridge chip disposed between the memory chips and the external terminal group. In such a semiconductor storage device, data is transferred between the host and the memory chips via the bridge chip. There is a request for the semiconductor memory device to input and output data at a transfer rate as high as possible between the host and the memory chip.

### BRIEF DESCRIPTION OF THE DRAWINGS

FIG. 1 is a schematic diagram illustrating an exemplary configuration of a memory system according to a first embodiment;

FIG. 2 is a diagram illustrating data transfer through a bridge chip with a transfer-rate scale factor of 1 in the first embodiment;

FIG. 3 is a diagram illustrating data transfer through a bridge chip with a transfer-rate scale factor of 2 in the first embodiment;

FIG. 4 is a diagram illustrating data transfer through a bridge chip with a transfer-rate scale factor of 4 in the first embodiment;

FIG. 5 is a schematic diagram for explaining a data splitting method by a splitter/concatenator circuit in the first embodiment;

FIG. 6 is a schematic diagram illustrating an exemplary configuration of a partial circuit included in the splitter/concatenator circuit for splitting data received via a host-side channel into two pieces in the first embodiment;

FIG. 7 is a schematic diagram for illustrating a data concatenating method by the splitter/concatenator circuit of the first embodiment;

FIG. 8 is a schematic diagram illustrating an exemplary configuration of a partial circuit included in the splitter/concatenator circuit for concatenating two pieces of data received via different NAND-side channels in the first embodiment;

FIG. 9 is a flowchart illustrating an exemplary operation of setting a transfer-rate scale factor in the first embodiment;

FIG. 10 is a timing chart illustrating various signal waveforms in a write operation of a memory system according to the first embodiment;

FIG. 11 is a timing chart illustrating various signal waveforms in a read operation of the memory system according to the first embodiment;

FIG. 12 is a schematic diagram illustrating an exemplary configuration of a memory system according to a second embodiment;

FIG. 13 is a schematic diagram for explaining a data splitting method by a splitter/concatenator circuit of the second embodiment;

FIG. 14 is a schematic diagram illustrating an exemplary configuration of a partial circuit included in the splitter/concatenator circuit of the second embodiment for splitting data received via a host-side channel into two pieces;

FIG. 15 is a schematic diagram for explaining a data concatenating method by the splitter/concatenator circuit of the second embodiment;

FIG. 16 is a diagram illustrating an exemplary configuration of a partial circuit for concatenating two pieces of data received via different NAND-side channels;

FIG. 17 is a timing chart illustrating various signal waveforms in a write operation of a memory system according to the second embodiment;

FIG. 18 is a timing chart illustrating various signal waveforms in a read operation of the memory system according to the second embodiment;

FIG. 19 is a schematic diagram illustrating a configuration of a host-side channel (i.e., channel CH0) according to a first modification of the second embodiment;

FIG. 20 is a schematic diagram for explaining operation of a splitter/concatenator circuit according to the first modification of the second embodiment;

FIG. 21 is a timing chart illustrating various signal waveforms in an operation of a memory system according to the first modification of the second embodiment;

FIG. 22 is a schematic diagram illustrating a configuration of a host-side channel according to a second modification of the second embodiment;

FIG. 23 is a timing chart illustrating various signal waveforms in an operation of a memory system according to the second modification of the second embodiment; and

FIG. 24 is a schematic diagram illustrating an exemplary configuration of a memory system according to a third embodiment.

### DETAILED DESCRIPTION

According to one embodiment, in general, a semiconductor memory device includes a plurality of first chips and a second chip. The second chip is connectable to a host via a first channel and connected to the plurality of first chips via M second channels where M is a natural number of two or more. The second chip is configured to, in response to receipt of first data via the first channel at a transfer rate N times higher than a transfer rate per a single second channel where N is a natural number of two or more and M or less, sort the first data into N pieces in a unit of a bus width of the first channel to split the first data into N pieces of second data, and transmit the N pieces of second data to N of the plurality of first chips corresponding to N of the M second channels in parallel via the N second channels; and, in response to receipt of L pieces of third data in parallel from L of the M second channels where L is a natural number of two or more and M or less, generate a single piece of fourth data by concatenating the L pieces of third data in the unit of the bus width of the first channel, and transmit the fourth data via the first channel at a transfer rate L times higher than a transfer rate per the single second channel.

A memory system according to an embodiment includes a host and a semiconductor memory device. The semiconductor memory device includes a bridge chip and a plurality of memory chips. The plurality of memory chips is an exemplary first chip group. The bridge chip is an exemplary second chip.

The memory chips are connected to the host via the bridge chip. The memory chips each include, for example, a non-volatile memory such as a NAND flash memory.

In order to increase the memory capacity of a memory system, the number of memory chips included in a semiconductor memory device has been increasing. In view of this, memory vendors dispose the bridge chip between the host and the memory chips for the purpose of reducing electric load applied on the connection between the host and the memory chips.

In an embodiment, the bridge chip is connected to M channels, each of which is connected to one or more memory chips where M is a natural number of two or more. Thus, the memory chips are connected to the bridge chip via the M channels. The bridge chip transfers data to the N memory chips in parallel using N channels in parallel where N is a natural number of two or more and M or less. The bridge chip transfers data to the host at a transfer rate N times higher than a transfer rate per channel. Thereby, the semiconductor memory device is capable of inputting and outputting data at a higher transfer rate.

Hereinafter, semiconductor storage devices and memory systems according to embodiments will be referred to in detail with reference to the accompanying drawings. The following embodiments are presented for illustrative purposes only and unintended to limit the scope of the present invention.

### First Embodiment

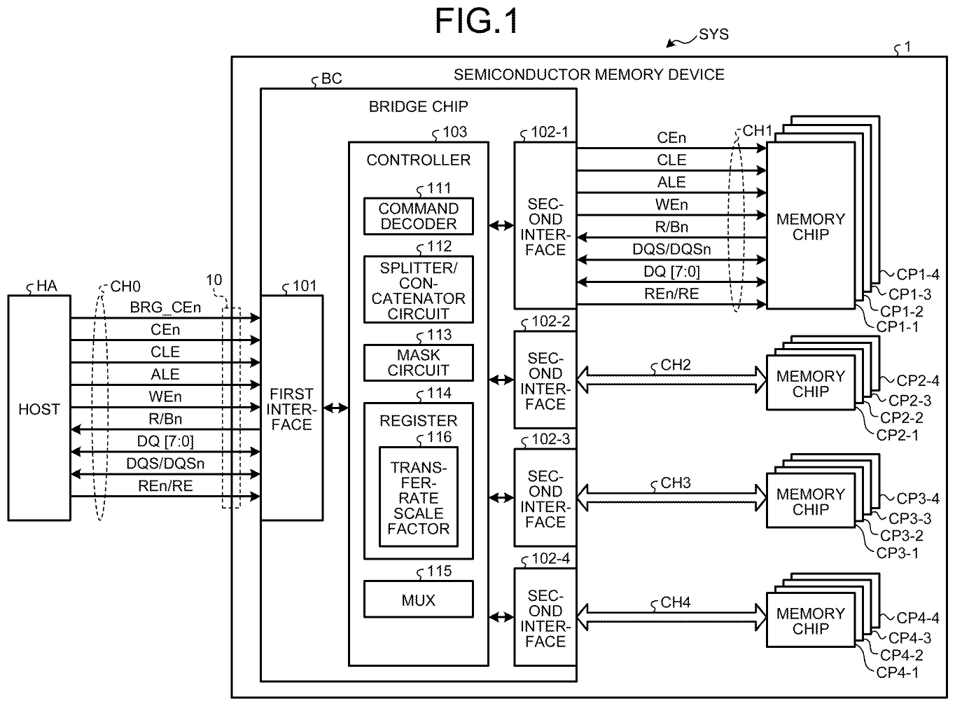

FIG. 1 is a schematic diagram illustrating an exemplary configuration of a memory system SYS according to a first embodiment.

The memory system SYS includes a semiconductor memory device 1 having an external terminal group 10, and a host HA. The semiconductor memory device 1 includes a bridge chip BC and a plurality of memory chips CP. In the example illustrated in FIG. 1, the semiconductor memory device 1 includes 16 memory chips CP, that is, memory chips CP1-1 to CP1-4, CP2-1 to CP2-4, CP3-1 to CP3-4, and CP4-1 to CP4-4).

Each memory chip CP is, for example, a non-volatile memory chip such as a NAND flash memory. In the semiconductor memory device 1, the peripheries of the bridge chip BC and the memory chips CP1-1 to CP1-4, CP2-1 to CP2-4, CP3-1 to CP3-4, and CP4-1 to CP 4-4 may be sealed with a mold resin.

The host HA may be a device such as a controller or may be a processor, included in an electronic device such as a computer or a mobile terminal, to control the semiconductor memory device 1. The semiconductor memory device 1 is connected to the host HA via a channel CH0 being a wired communication path. The semiconductor memory device 1 and the host HA are connected to each other via the channel CH0, which is configured in compliance with a given standard. In a case of using NAND flash memories as the memory chips CP, the given standard can be, for example, toggle double-data-rate (DDR) standard or ONFi standard.

The bridge chip BC is electrically connected to the external terminal group 10 and M channels where M is a natural number of two or more. As an example, M is set to four, and the four channels are denoted by CH1, CH2, CH3, and CH4.

The groups of the memory chips CP1-1 to CP1-4, CP2-1 to CP2-4, CP3-1 to CP3-4, and CP4-1 to CP4-4 are respectively connected to the bridge chip BC via the four channels CH1, CH2, CH3, and CH4, which are configured in compliance with a given standard. Specifically, the memory chips CP1-1 to CP1-4 are connected to the channel CH1. The memory chips CP2-1 to CP2-4 are connected to the channel CH2. The memory chips CP3-1 to CP3-4 are connected to the channel CH3. The memory chips CP4-1 to CP4-4 are connected to the channel CH4. When the memory chips CP1-1 to CP1-4, CP2-1 to CP2-4, CP3-1 to CP3-4, and CP4-1 to CP4-4 are NAND flash memories, the given standard can be, for example, toggle DDR standard.

In the following, each of the memory chips CP1-1 to CP1-4, CP2-1 to CP2-4, CP3-1 to CP3-4, and CP4-1 to CP4-4 may be referred to as a memory chip CP. Each of the memory chips CP1-1 to CP1-4 may be referred to as a memory chip CP1. Each of the memory chips CP2-1 to CP2-4 may be referred to as a memory chip CP2. Each of the memory chips CP3-1 to CP3-4 may be referred to as a memory chip CP3. Each of the memory chips CP4-1 to CP4-4 may be referred to as a memory chip CP4.

The number of the memory chips CP included in the semiconductor memory device 1 is not limited to 16. The number of the channels connecting the bridge chip BC and the memory chips CP to each other is not limited to four.

Hereinafter, it is assumed that the memory chips CP be NAND flash memories and the given standard be the toggle DDR standard.

The bridge chip BC is electrically connected to the host HA via the external terminal group 10 and the channel CH0.

The channel CH0 includes a signal line for transferring a bridge chip enable signal BRG_CEn, a signal line for transferring a chip enable signal CEn, a signal line for transferring a command latch signal CLE, a signal line for transferring an address latch signal ALE, a signal line for transferring a write enable signal WEn, a signal line for transferring a ready/busy signal R/Bn, signal lines for transferring a data signal DQ[7:0] having a given bit width (8 bits herein, as an example), signal lines for transferring a data strobe signal DQS/DQSn, and signal lines for transferring a read enable signal REn/RE. The letter “n” attached to the end of the signal signs represents that the signals operate by negative logic. Whether the signals operate by negative logic or positive logic can be freely designed.

The bridge chip enable signal BRG_CEn is enabled (or activated) for transmitting a command for controlling the bridge chip BC. When receiving a signal, i.e., a command, an address, and data, during an active period of the bridge chip enable signal BRG_CEn, the bridge chip BC interprets the signal as a signal addressed to itself. Further, when receiving a signal from the host HA during the active period of the bridge chip enable signal BRG_CEn, the bridge chip BC refrains from transferring the signal to any of the memory chips CP. When receiving a signal from the host HA during an inactive period of the bridge chip enable signal BRG_CEn, the bridge chip BC transfers the signal to the memory chip CP to be accessed.

The chip enable signal CEn serves to place the memory chip being an access target in an enable state. The data strobe signal DQS/DQSn indicates timing at which the data signal DQ[7:0] being data is acquired. That is, the data strobe signal DQS/DQSn serves as a timing signal for data transfer. The data strobe signal DQS/DQSn serves as a differential signal including a data strobe signal DQS and a data strobe signal DQSn. The command latch enable signal CLE indicates that the data signal DQ[7:0] is a command. The address latch enable signal ALE indicates that the data signal DQ[7:0] is an address. The write enable signal WEn serves to provide an instruction for a transmission destination (counterpart device) to acquire the transmitted data signal DQ[7:0] being a command or an address. The read enable signal REn/RE indicates output timing of the data signal DQ[7:0] by the memory chip CP. The read enable signal REn/RE serves as a differential signal including a read enable signal RE and a read enable signal REn. The ready/busy signal R/Bn indicates a ready state (Ry) or a busy state (By). The ready/busy signal R/Bn to be transferred through the channel CH0 is generated from the ready/busy signal R/Bn for the channel CH1 and the ready/busy signal R/Bn for the channel CH2 via wired connection, for example. The ready/busy signal R/Bn to be transferred through the channel CH0 is not limited to such an example. As an example, the channel CH0 may include one signal line for transferring a ready/busy signals R/Bn_1 being the ready/busy signal R/Bn for the channel CH1, and a signal line for transferring a ready/busy signal R/Bn_2 being the ready/busy signal R/Bn for the channel CH2.

In the following, an operation mode of the bridge chip BC, in which the bridge chip BC interrupts the transfer of a signal from the host HA to the memory chip CP and interprets the signal as a signal addressed to itself, will be referred to as a bridge control mode. An operation mode of the bridge chip BC, in which the bridge chip BC transfers a signal from the host HA to the memory chip CP, will be referred to as a non-bridge control mode.

Each of the channels CH1, CH2, CH3, and CH4 can transmit and receive the same signal groups as the signal groups transmitted and received between the host HA and the bridge chip BC except for the bridge chip enable signal BRG_CEn. Specifically, each of the channels CH1, CH2, CH3, and CH4 includes a signal line for transferring the chip enable signal CEn, a signal line for transferring the command latch signal CLE, a signal line for transferring the address latch signal ALE, a signal line for transferring the write enable signal WEn, a signal line for transferring the ready/busy signal R/Bn, a signal line group for transferring a data signal DQ[15:0], signal lines for transferring the data strobe signal DQS/DQSn, and signal lines for transferring the read enable signal REn/RE.

Among the channels CH1, CH2, CH3, and CH4, FIG. 1 illustrates only the signal line group constituting the channel CH1 in detail and omits illustrating the signal line groups constituting the channels CH2, CH3, and CH4.

The following will omit a description of the data strobe signal DQSn between the data strobe signals DQS/DQSn and describe the data strobe signal DQS alone for the sake of simpler explanation. Likewise, only the read enable signal RE of the read enable signals REn/RE will be described, and a description of the read enable signal REn will be omitted.

Hereinafter, the channel CH0 may be referred to as a host-side channel, and the channels CH1, CH2, CH3, and CH4 may be referred to as NAND-side channels. The host-side channel is an exemplary first channel. Each of the NAND-side channels is an exemplary second channel.

Also, the signals transferred through the NAND-side channels are denoted by #X where X is a numerical value of one or more and M or less corresponding to a channel number. For example, the data signal DQ[7:0] transferred through the channel CH2 is denoted by DQ #2[7:0].

Data is transferred between the host HA and the bridge chip BC via the host-side channel. Between the bridge chip BC and the 16 memory chips CP, data is transferred via one or more NAND-side channels. The data transfer includes data transfer from the host HA to one or more memory chips CP and data transfer from one or more memory chips CP to the host HA. The former data transfer operation is referred to as a write operation. The latter data transfer operation is referred to as a read operation.

When receiving data via the host-side channel at a transfer rate N times higher than via the NAND-side channels, the bridge chip BC splits the data into N pieces and transmits the N pieces of data to the memory chip group CP in parallel via the N NAND-side channels, respectively, where N is a natural number of two or more and M (herein, four) or less. When receiving N pieces of data in parallel from N of M NAND-side channels, the bridge chip BC concatenates the N pieces of data into one piece of data and transmits the data to the host HA via the host-side channel at a transfer rate N times higher than a transfer rate per NAND-side channel.

The bridge chip BC includes a first interface 101, four second interfaces 102, and a controller 103.

The first interface 101 serves as a PHY circuit which transmits and receives electric signals to and from the host HA via the channel CH0.

Among the four second interfaces 102, the second interface 102-1 serves as a PHY circuit which transmits and receives electric signals to and from the four memory chips CP1 via the channel CH1. The second interface 102-2 serves as a PHY circuit which transmits and receives electric signals to and from the four memory chips CP2 via the channel CH2. The second interface 102-3 serves as a PHY circuit which transmits and receives electric signals to and from the four memory chips CP3 via the channel CH3. The second interface 102-4 serves as a PRY circuit which transmits and receives electric signals to and from the four memory chips CP4 via the channel CH4.

The controller 103 is disposed between the first interface 101 and the four second interfaces 102. The controller 103 controls transmission and reception of signals between the first interface 101 and the four second interfaces 102.

The controller 103 includes a command decoder 111, a splitter/concatenator circuit 112, a mask circuit 113, a register 114, and a multiplexer (MUX) 115.

The command decoder 111 serves to analyze commands received from the host HA via the channel CH0. The command decoder 111 can issue commands with respect to the memory chips CP in accordance with results of the analysis.

In response to receipt of a data transfer command together with an address, the command decoder 111 selects one or more of the four NAND-side channels as a data transfer path or paths according to the address.

The multiplexer 115 serves to switch data transfer paths for one or more of the four second interfaces 102 in accordance with the data transfer paths selected by the command decoder 111.

The mask circuit 113 is capable of interrupting a signal supply to the memory chips CP in accordance with the bridge chip enable signal BRG_CEn. During an active period of the bridge chip enable signal BRG_CEn, the mask circuit 113 interrupts a signal supply to the memory chips CP. During an inactive period of the bridge chip enable signal BRG_CEn, the mask circuit 113 allows the signals to the memory chips CP to pass therethrough. In other words, the mask circuit 113 implements switching between the bridge control mode and the non-bridge control mode in accordance with the bridge chip enable signal BRG_CEn.

In a write operation, the splitter/concatenator circuit 112 receives data from the host HA via the channel CH0 and splits the data into N pieces. The splitter/concatenator circuit 112 transmits the N pieces of split data to N memory chips CP in parallel via N different channels. The splitter/concatenator circuit 112 allows the transfer rate of each of the N pieces of data to match the transfer rate per NAND-side channel by setting the transfer rate of each of the N pieces of divisional data to 1/N of the transfer rate before the division.

In a read operation, the splitter/concatenator circuit 112 receives pieces of data from the N memory chips CP in parallel via the N different channels and concatenates them. The splitter/concatenator circuit 112 transmits the concatenated data to the host HA via the channel CH0. The splitter/concatenator circuit 112 allows the transfer rate of the concatenated data to match a transfer rate N times higher than the transfer rate per NAND-side channel by setting the transfer rate of the concatenated data to N times higher than the transfer rate of each of the received N pieces of data.

Thereby, the splitter/concatenator circuit 112 can set the transfer rate between the host HA and the bridge chip BC N times higher than the transfer rate between the bridge chip BC and the memory chips CP in a unit of channels.

The transfer rate is determined by multiplication of a bus width and a frequency. In the example illustrated in FIG. 1, the signal lines for transferring the data signals DQ[7:0] included in the host-side channel and the signal lines for transferring the data signals DQ[7:0] included in the NAND-side channel both have a bus width of 8 bits. Thus, by setting the transfer frequency of the host-side channel N times higher than the transfer frequency of the NAND-side channel, the transfer rate of the host-side channel is set to N times higher than the transfer rate per NAND-side channel.

Hereinafter, the bus width of the host-side channel refers to the bus width of the signal lines for transferring the data signal DQ included in the host-side channel. The bus width of the NAND-side channels refers to the bus width of the signal lines for transferring the data signal DQ included in one NAND-side channel. In the example illustrated in FIG. 1, the host-side channel and the NAND-side channels have a bus width of 8 bits.

The transfer rate in the host-side channel is controlled by the host HA. That is, in a write operation the host HA transfers data to the bridge chip BC at a frequency N times higher than the data transfer frequency of the NAND-side channel. In a read operation the host HA causes the bridge chip BC to transfer data to the host HA at the frequency N times higher than the data transfer frequency of the NAND-side channel.

The register 114 is a memory to which various control information for the operation of the bridge chip BC is written. In the embodiment, a transfer-rate scale factor 116 is written to the register 114. The transfer-rate scale factor 116 refers to a set scale factor of the transfer rate of the host-side channel with respect to the transfer rate of the NAND-side channels. In other words, the transfer-rate scale factor 116 represents a set value of “N”. That is, the bridge chip BC is variable in terms of the value N. The transfer-rate scale factor 116 can be set to one in addition to two or more and H or less.

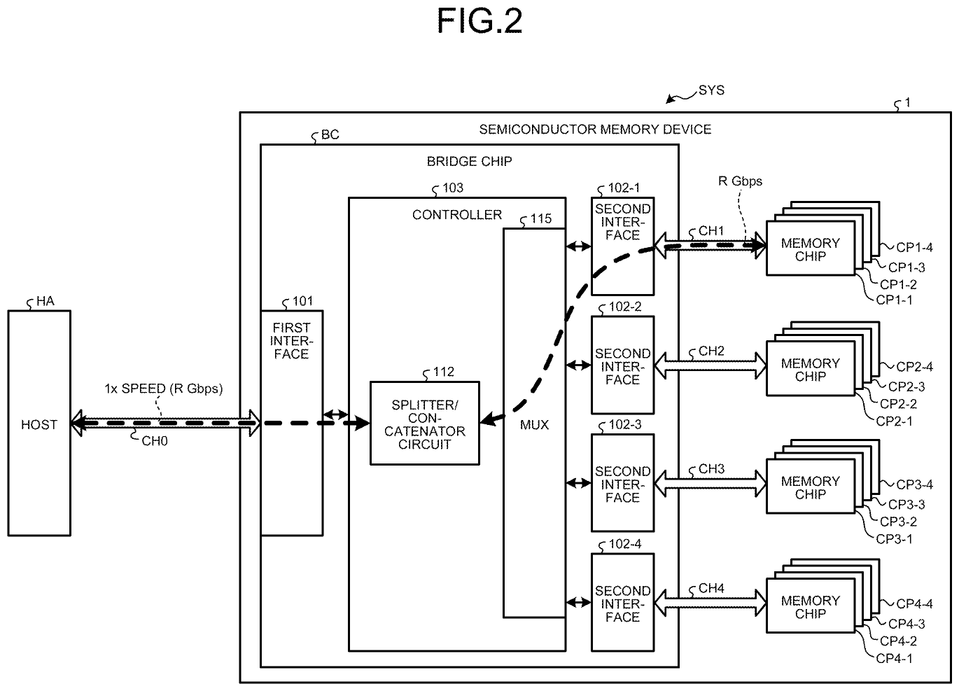

FIG. 2 is a diagram illustrating data transfer from the bridge chip with a transfer-rate scale factor of 1 in the first embodiment. Hereinafter, the transfer rate of the NAND-side channel will be denoted by R[Gbps].

At the transfer-rate scale factor 116 of 1, the bridge chip BC transfers data between the host-side channel (i.e., CH0) and one of the NAND-side channels. In the example illustrated in FIG. 2, the one NAND-side channel is defined as the channel CH1.

In a write operation, the splitter/concatenator circuit 112 receives data via the host-side channel and the first interface 101 at the transfer rate R[Gbps] the same as the transfer rate of the NAND-side channel and outputs the received data without changing the transfer rate. The data is output from the splitter/concatenator circuit 112 and transmitted to the memory chip CP as a destination via the multiplexer 115, the second interface 102-1, and the channel CH1.

In a read operation, the splitter/concatenator circuit 112 receives data at the transfer rate R[Gbps] via the channel CH1, the second interface 102-1, and the multiplexer 115 and outputs the received data without changing the transfer rate. The data is output from the splitter/concatenator circuit 112 and transmitted to the host HA via the first interface 101 and the channel CH0.

In this manner, at the transfer-rate scale factor 116 of 1, the host-side channel transfers data at R[Gbps]. In other words, the host-side channel transfers data at 1× speed with reference to the transfer rate of the NAND-side channel.

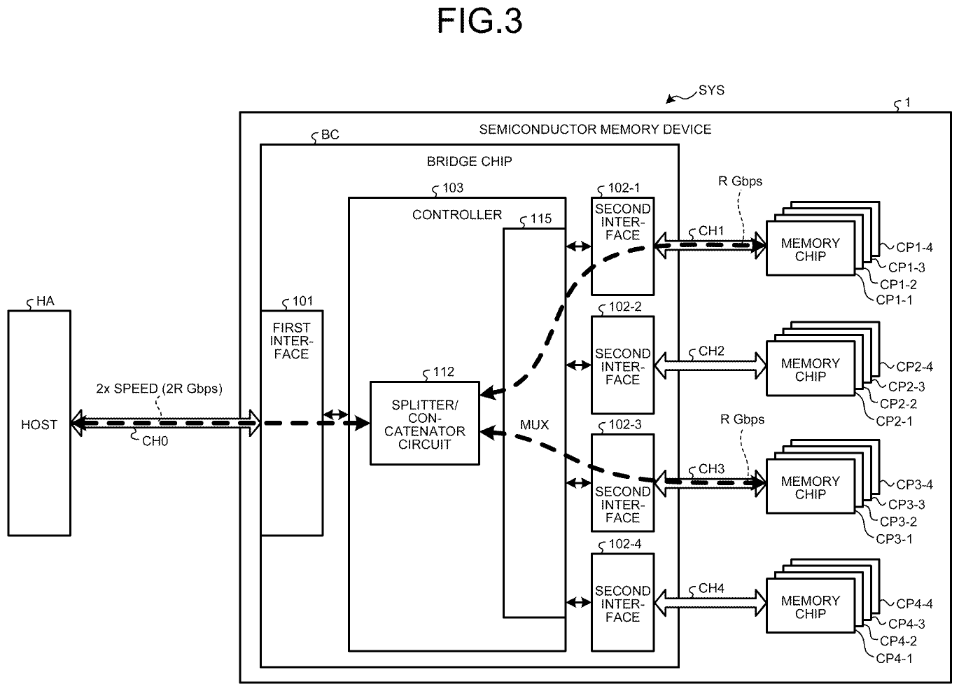

FIG. 3 is a diagram illustrating data transfer from the bridge chip BC with the transfer-rate scale factor 116 of 2 in the first embodiment.

At the transfer-rate scale factor 116 of 2, the bridge chip BC transfers data between the host-side channel (i.e., CH0) and two of the NAND-side channels. In the example illustrated in FIG. 3, the two NAND-side channels are defined as the channel CH1 and the channel CH3.

In a write operation, the splitter/concatenator circuit 112 receives two pieces of data via the host-side channel and the first interface 101 at the transfer rate 2R[Gbps] twice higher than the transfer rate of the NAND-side channels, and splits the received data into two pieces. Then, the splitter/concatenator circuit 112 individually outputs the two pieces of divisional data at the transfer rate R[Gbps] of half that at the time of the reception. One of the two pieces of data output from the splitter/concatenator circuit 112 is transmitted to the memory chip CP as a destination via the multiplexer 115, the second interface 102-1, and the channel CH1. The other of the two pieces of data output from the splitter/concatenator circuit 112 is transmitted to another memory chip CP as a destination via the multiplexer 115, the second interface 102-3, and the channel CH3.

In a read operation, the splitter/concatenator circuit 112 receives two pieces of data at the transfer rate R[Gbps] via the channel CH1, the second interface 102-1, and the multiplexer 115 and via the channel CH3, the second interface 102-3, and the multiplexer 115. The splitter/concatenator circuit 112 concatenates the two pieces of data into one and outputs the concatenated data at the transfer rate 2R[Gbps] twice higher than the transfer rate of the NAND-side channels. The data is output from the splitter/concatenator circuit 112 and transmitted to the host HA via the first interface 101 and the channel CH0.

In this manner, at the transfer-rate scale factor 116 of 2, the bridge chip BC can concurrently transfer data through two paths, i.e., between the host HA and one of the memory chips CP and between the host HA and another one of the memory chips CP. Data transfer through each of paths may be referred to as a stream. That is, at the transfer-rate scale factor 116 of 2, the bridge chip BC can concurrently perform two streams of data transfer. The host-side channel can transfer data at 2× speed, i.e., double the transfer rate of the NAND-side channels.

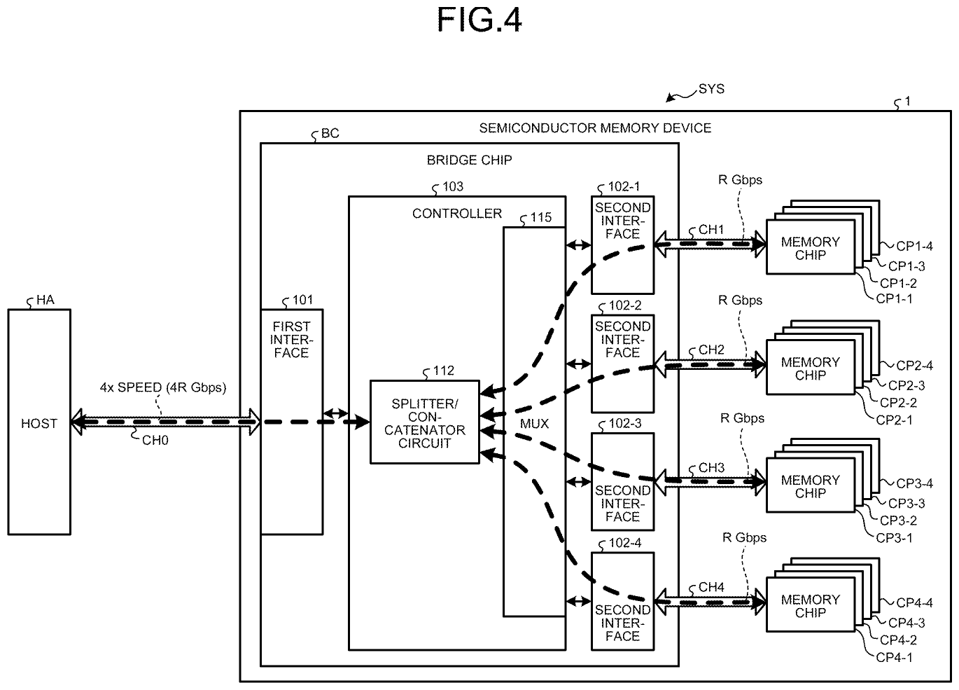

FIG. 4 is a diagram illustrating data transfer from the bridge chip BC with the transfer-rate scale factor 116 of 4 in the first embodiment.

At the transfer-rate scale factor 116 of 4, the bridge chip BC transfers data between the host-side channel (i.e., CH0) and four of the NAND-side channels. In the example illustrated in FIG. 4, the four NAND-side channels are the channels CH1, CH2, CH3, and CH4.

In a write operation, the splitter/concatenator circuit 112 receives data via the host-side channel and the first interface 101 at a transfer rate 4R[Gbps] four times higher than the transfer rate of the NAND-side channels, and splits the received data into four pieces. The splitter/concatenator circuit 112 individually outputs the four pieces of divisional data at the transfer rate R[Gbps] one-quarter of the transfer rate at the time of the reception. One of the four pieces of data is output from the splitter/concatenator circuit 112 and transmitted to the memory chip CP as a destination at the transfer rate R[Gbps] via the multiplexer 115, the second interface 102-1, and the channel CH1. Another one of the four pieces of data is output from the splitter/concatenator circuit 112 and transmitted to the memory chip CP as a destination at a transfer rate R[Gbps] via the multiplexer 115, the second interface 102-2, and the channel CH2. Another one of the four pieces of data is output from the splitter/concatenator circuit 112 and transmitted to the memory chip CP as a destination at the transfer rate R[Gbps] via the multiplexer 115, the second interface 102-3, and the channel CH3. The last one of the four pieces of data is output from the splitter/concatenator circuit 112 and transmitted to the memory chip CP as a destination at the transfer rate R[Gbps] via the multiplexer 115, the second interface 102-4, and the channel CH4.

In a read operation, the splitter/concatenator circuit 112 can receive pieces of data at the transfer rate R[Gbps] in parallel via the channel CH1, the second interface 102-1, and the multiplexer 115, via the channel CH2, the second interface 102-2, and the multiplexer 115, via the channel CH3, the second interface 102-3, and the multiplexer 115, and via the channel CH4, the second interface 102-4, and the multiplexer 115, respectively. The splitter/concatenator circuit 112 thus receives four pieces of data in parallel and concatenates them into one, and outputs the concatenated data at the transfer rate 4R[Gbps] four times higher than the transfer rate of the NAND-side channels. The data is output from the splitter/concatenator circuit 112 and transmitted to the host HA via the first interface 101 and the channel CH0.

In this manner, at the transfer-rate scale factor 116 of 4, the bridge chip BC can concurrently transfer data between the host HA and the four different memory chips CP through the four paths. The host-side channel can transfer data at 4× speed, i.e., four times higher than the transfer rate of the NAND-side channels.

Herein, the transfer-rate scale factor 116 is set to one, two, and four by way of example. Alternatively, the transfer-rate scale factor 116 may be set to three. In this case, the splitter/concatenator circuit 112 receives data from the host HA and splits it into three pieces or receive three pieces of data from three NAND-side channels in parallel and concatenates them into one.

As such, upon receipt of data from the host HA, the splitter/concatenator circuit 112 splits the data into the number of pieces indicated by the transfer-rate scale factor 116 or receives and concatenates the number of pieces of data via the number of NAND-side channels indicated by the transfer-rate scale factor 116. The splitter/concatenator circuit 112 then transfers the data via the host-side channel at the transfer rate multiplied by the transfer-rate scale factor 116.

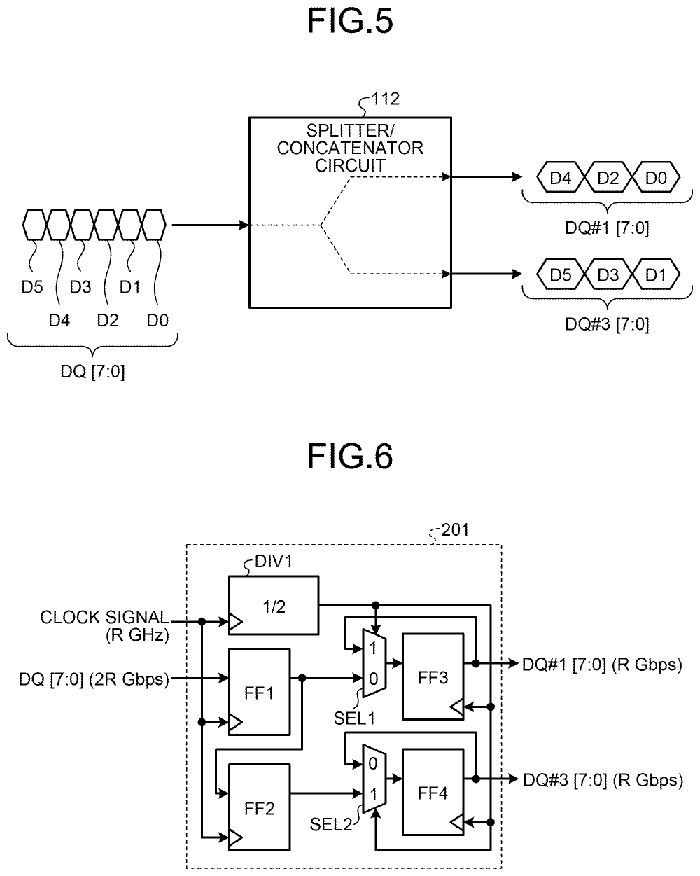

FIG. 5 is a schematic diagram for explaining a data splitting method by the splitter/concatenator circuit 112 of the first embodiment. In FIG. 5, the transfer-rate scale factor 116 is set to two and the channel CH1 and the channel CH3 are selected as data transfer paths by way of example.

The bridge chip BC receives data from the host HA via the channel CH0 having an 8-bit bus width, and provides the data to the splitter/concatenator circuit 112. That is, the data from the host HA is input to the splitter/concatenator circuit 112 on an 8-bit (i.e., 1 byte) basis. In FIG. 5, data DY (Y is an integer of zero or more) represents transfer data of a size in units of transfer in the host-side channel, that is, a size of the bus width (1 byte herein) of the channel CH0. When receiving a string of data D0, data D1, data D2, data D3, data D4, and data D5 from the host-side channel, the splitter/concatenator circuit 112 alternately sorts the data D0, the data D1, the data D2, the data D3, the data D4, and the data D5 into two paths in units of transfer in the host-side channel, i.e., in units of data DY. Thereby, the splitter/concatenator circuit 112 outputs a data string D0, D2, and D4 to one of the two paths and outputs the data string D1, D3, and D5 to the other path.

The data string D0, D2, and D4 is output from the splitter/concatenator circuit 112 and input, as a data signal DQ #1[7:0], to one of the NAND-side channels (in this example, the channel CH1) via the multiplexer 115 and the second interface 102. In addition, the data string D1, D3, and D5 is input, as a data signal DQ #3[7:0], to another NAND-side channel (in this example, the channel CH3) via the multiplexer 115 and the second interface 102. In order to allow the transfer rate of the data signal DQ[7:0] input from the host-side channel to coincide with the total transfer rate of the data signal DQ #1[7:0] and the data signal DQ #3[7:0] to be output to the NAND-side channels, the splitter/concatenator circuit 112 sets the respective transfer frequencies of the data signal DQ #1[7:0] and the data signal DQ #3[7:0] to half the transfer frequency of one data signal DQ[7:0] input from the host-side channel.

In this manner, the splitter/concatenator circuit 112 split the data received from the host-side channel into two by sorting the data into the two paths alternately in units of transfer (in this example, 1-byte).

At the transfer-rate scale factor 116 of 3 or more, the splitter/concatenator circuit 112 sequentially sorts the data received from the host-side channel into the number of paths indicated by the transfer-rate scale factor 116 in units of transfer (in this example, 1-byte) in the same manner as above. Thereby, the splitter/concatenator circuit 112 can split the data received from the host-side channel into the number of pieces of data indicated by the transfer-rate scale factor 116.

In order to be able to deal with any of the transfer-rate scale factors 116 of 2, 3, and, 4, the splitter/concatenator circuit 112 can include, for example, a partial circuit for splitting the data received via the host-side channel into two pieces, a partial circuit for splitting the data received via the host-side channel into three pieces, and a partial circuit for splitting the data received via the host-side channel into four pieces.

As an example, FIG. 6 illustrates an exemplary configuration of a partial circuit 201 included in the splitter/concatenator circuit 112 for splitting the data received via the host-side channel into two pieces. In the example illustrated in FIG. 6, the partial circuit 201 includes a ½ frequency divider DIV1, four flip-flops FF1, FF2, FF3, and FF4, and two selectors SEL1 and SEL2.

A clock signal having a certain frequency is input in common to a clock input terminal of the ½ frequency divider DIV1, a clock input terminal of the flip-flop FF1, and a clock input terminal of the flip-flop FF2. Referring to FIG. 6, the clock signal is referred to as an input clock. The input clock may be generated from the strobe signal (data strobe signal DQS or read enable signal REn) input from the host HA or may be a clock signal generated inside the controller 103. The frequency of the input clock is defined as R[GHz].

The ½ frequency divider DIV1 divides the frequency of the input clock signal in half for output. In FIG. 6, the clock signal output by the ½ frequency divider DIV1 is referred to as a frequency-divided clock. The frequency-divided clock is input in common to a selection-signal input terminal of the selector SEL1, a selection-signal input terminal of the selector SEL2, a clock input terminal of the flip-flop FF3, and a clock input terminal of the flip-flop FF4.

The data signal DQ[7:0] is received at the transfer rate 2R[Gbps] from the host-side channel and input to a D-input terminal of the flip-flop FF1. A Q-output terminal of the flip-flop FF1 is connected to a D-input terminal of the flip-flop FF2. Thus, the flip-flop FF2 can acquire the data DY at a delayed timing by one clock of the input clock from the timing at which the flip-flop FF1 has acquired data DY.

The Q-output terminal of the flip-flop FF1 is also connected to one of two input terminals of the selector SEM. The Q-output terminal of the flip-flop FF2 is connected to one of two input terminals of the selector SEL2.

An output terminal of the selector SEL1 is connected to a D-input terminal of the flip-flop FF3. A Q-output terminal of the flip-flop FF3 is connected to the other of the two input terminals of the selector SELL

In response to the frequency-divided clock indicating zero, the selector SEL1 outputs the signal input from the Q-output terminal of the flip-flop FF1. In response to the frequency-divided clock indicating 1, the selector SEL1 outputs the signal input from the Q-output terminal of the flip-flop FF3.

An output terminal of the selector SEL2 is connected to a D-input terminal of the flip-flop FF4. The Q-output terminal of the flip-flop FF4 is connected to the other of the two input terminals of the selector SEL2.

In response to the frequency-divided clock indicating zero, the selector SEL2 outputs the signal input from the Q-output terminal of the flip-flop FF4. In response to the frequency-divided clock indicating 1, the selector SEL2 outputs the signal input from the Q-output terminal of the flip-flop FF2.

As configured as above, the partial circuit 201 sorts and splits the data signal DQ[7:0] input from the host-side channel into two in units of transfer in the host-side channel. The partial circuit 201 can output one of the two pieces of divisional data from the Q-output terminal of the flip-flop FF3 at the transfer rate R[Gbps] and output the other of the two pieces of divisional data from the Q-output terminal of the flip-flop FF4 at the transfer rate R[Gbps]. The data output from the Q-output terminal of the flip-flop FF3 is transmitted, for example, to the channel CH1 as the data signal DQ #1[7:0]. The data output from the Q-output terminal of the flip-flop FF4 is transmitted, for example, to the channel CH3 as the data signal DQ #3[7:0].

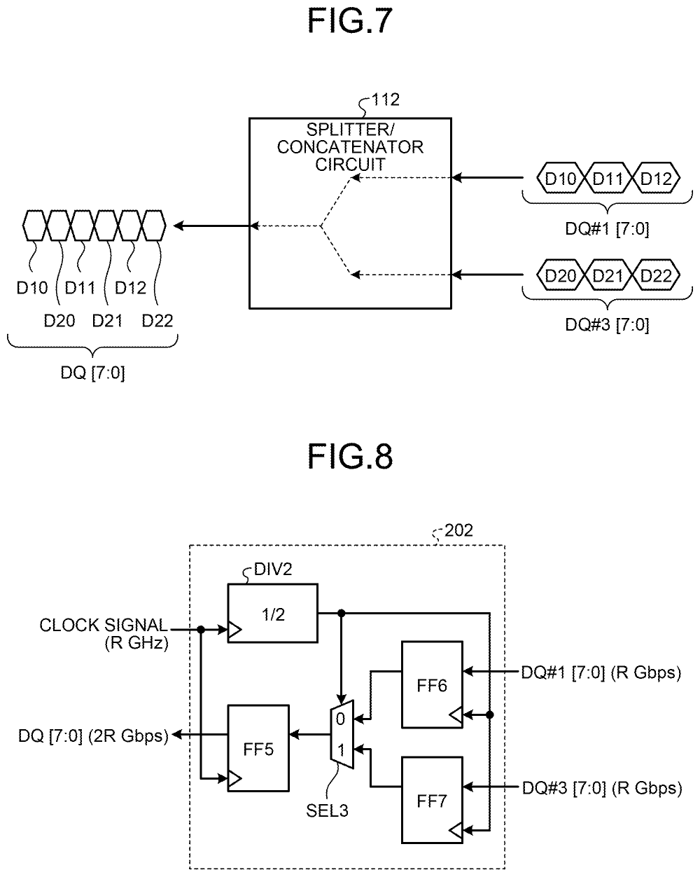

FIG. 7 is a schematic diagram for explaining a data concatenating method by the splitter/concatenator circuit 112 of the first embodiment. In FIG. 7, the transfer-rate scale factor 116 is set to two and the channel CH1 and the channel CH3 are selected as data transfer paths by way of example.

FIG. 7 illustrates an example that the bridge chip BC receives the data signal DQ #1[7:0], i.e., a data string D10, D11, and D12 from the channel CH1 at the transfer rate R[Gbps], and in parallel receives the data signal DQ #3[7:0], i.e., a data string D20, D21, and D22 from the channel CH3 at the transfer rate R[Gbps]. In this example, the splitter/concatenator circuit 112 acquires the two data strings one by one in units of transfer in the host-side channel, in other words, in units of 1-byte data DY and sequentially concatenates the pieces of data DY in the order of acquisition. Thereby, the splitter/concatenator circuit 112 generates a data string including the data D10, the data D20, the data D11, the data D21, the data D12, and the data D22 in this order. The splitter/concatenator circuit 112 then outputs the string of data D10, data D20, data D11, data D21, data D12, and data D22.

The splitter/concatenator circuit 112 outputs one data string concatenated at a frequency twice higher than the transfer frequency at which the two data strings have been input. One data string as the data signal DQ[7:0] is transferred to the host HA via the host-side channel.

At the transfer-rate scale factor 116 of 3 or more, the splitter/concatenator circuit 112 can also generate a single data string from the number of data strings indicated by the transfer-rate scale factor 116 by sequentially acquiring pieces of data in units of transfer in the host-side channel (in this example, 1-byte) and concatenating the pieces of data in the order of acquisition in the same manner as above.

For example, in order to be able to deal with any of the transfer-rate scale factors 116 of 2, 3, and 4, the splitter/concatenator circuit 112 may include a partial circuit for concatenating two pieces of data received from two different NAND-side channels, a partial circuit for concatenating three pieces of data received from three different NAND-side channels, and a partial circuit for concatenating four pieces of data received from four different NAND-side channels.

As an example, FIG. 8 illustrates an exemplary configuration of a partial circuit 202 included in the splitter/concatenator circuit 112 for concatenating two pieces of data received from two different NAND-side channels. In the example of FIG. 8, the partial circuit. 202 includes a ½ frequency divider DIV2, three flip-flops FF5, FF6, and FF7, and one selector SEL3.

A clock signal having a certain frequency is input in common to a clock input terminal of the ½ frequency divider DIV2 and a clock input terminal of the flip-flop FF5. Referring to FIG. 8, the clock signal is referred to as an input clock. The input clock may be generated from the strobe signal (data strobe signal DQS or read enable signal REn) input from the host HA or may be a clock signal generated inside the controller 103. The frequency of the input clock is defined as R[GHz].

The ½ frequency divider DIV2 divides the frequency of the input clock signal in half for output. In FIG. 8, the clock signal output from the ½ frequency divider DIV2 will be referred to as a frequency-divided clock. The frequency-divided clock is input in common to a selection-signal input terminal of the selector SEL3, a clock input terminal of the flip-flop FF6, and a clock input terminal of the flip-flop FF7.

The data signal DQ #1[7:0] having an 8-bit width is received from the channel CH1 at the transfer rate R[Gbps] and input to a D-input terminal of the flip-flop FF6. The data signal DQ #3[7:0] having an 8-bit width is received from the channel CH3 at the transfer rate R[Gbps] and input to a D-input terminal of the flip-flop FF7. A Q-output terminal of the flip-flop FF6 is connected to one of two input, terminals of the selector SEL3. A Q-output terminal of the flip-flop FF7 is connected to the other of the two input terminals of the selector SEL3.

At the frequency-divided clock indicating zero, the selector SEL3 outputs the signal input from the Q-output terminal of the flip-flop FF6. At the frequency-divided clock indicating one, the selector SEL3 outputs the signal input from the Q-output terminal of the flip-flop FF7. The signal output from the selector SEL3 is input to a D-input terminal of the flip-flop FF5.

As configured as above, the partial circuit 202 can sequentially and alternately acquire and concatenate, in units of transfer in the host-side channel, the data signal DQ #1[7:0] having the 8-bit width received from the channel CH1 at the transfer rate R[Gbps] and the data signal DQ #3[7:0] having the 8-bit width received from the channel CH3 at the transfer rate R[Gbps], and output the resultant data from a Q-output terminal of the flip-flop FF5 at the transfer rate 2R[Gbps]. The data is output from the Q-output terminal of the flip-flop FF5 and transmitted to the host-side channel.

The following will describe an operation of the memory system SYS according to the first embodiment.

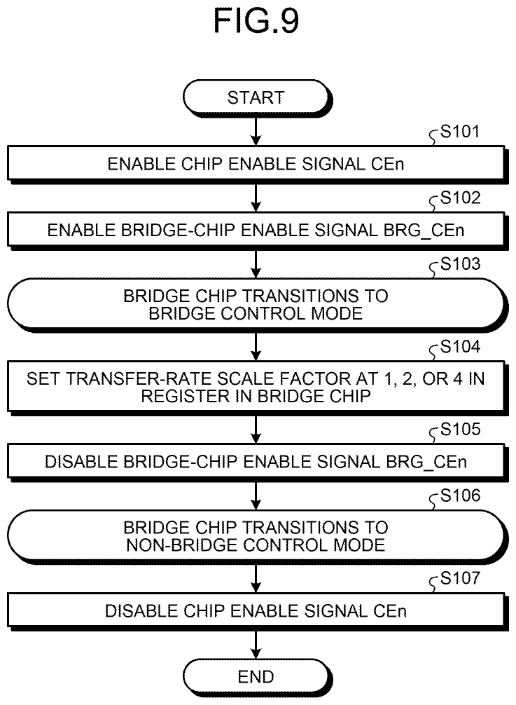

FIG. 9 is a flowchart illustrating an exemplary operation of setting the transfer-rate scale factor 116 in the first embodiment.

First, the host HA enables (or activates) the chip enable signal CEn (S101). The host HA then enables (or activates) the bridge chip enable signal BRG_CEn (S102).

In response to the enabled bridge chip enable signal BRG_CEn, the bridge chip BC transitions from the non-bridge control mode to the bridge control mode (S103).

The host HA sets the transfer-rate scale factor 116 to the register 114 in the bridge chip BC (S104).

For example, the host HA can set the transfer-rate scale factor 116 to the register 114 by transmitting the set feature command to the bridge chip BC. Receiving the set feature command in the bridge control mode, the bridge chip BC executes the set feature command without transferring the command to any of the memory chips CP. The host HA transmits the transfer-rate scale factor 116 together with the set feature command to the bridge chip BC, and the command decoder 111 thereof stores the transfer-rate scale factor 116 in the register 114 in accordance with the set feature command.

Alternatively, the host HA can set the transfer-rate scale factor 116 using a specific command. In the bridge control mode the bridge chip BC refrains from transferring any command to the memory chips CP. Thus, the vendor of the host HA can define a specific command to be executable by the bridge chip BC in the bridge control mode. The vendor can define a specific command for storing the transfer-rate scale factor 116 in the register 114 of the bridge chip BC, which allows the host HA to set the transfer-rate scale factor 116 using the specific command.

The transfer-rate scale factor 116 can be set to equal to or less than the number of the NAND-side channels connected to the bridge chip BC. As an example, the host HA can set the transfer-rate scale factor 116 to 1, 2, or 4.

After completion of setting the transfer-rate scale factor 116, the host HA disables (or inactivated) the bridge chip enable signal BRG_CEn (S105). As a result, the bridge chip BC transitions from the bridge control mode to the non-bridge control mode (S106). Subsequently, the host HA disables (or inactivated) the chip enable signal CEn (S107), completing the operation of setting the transfer-rate scale factor 116.

The host HA can execute the series of operations illustrated in FIG. 9 at any timing. The host HA can execute the series of operations illustrated in FIG. 9 not only in initially setting the transfer-rate scale factor 116 after startup of the memory system SYS but also in changing the set transfer-rate scale factor 116.

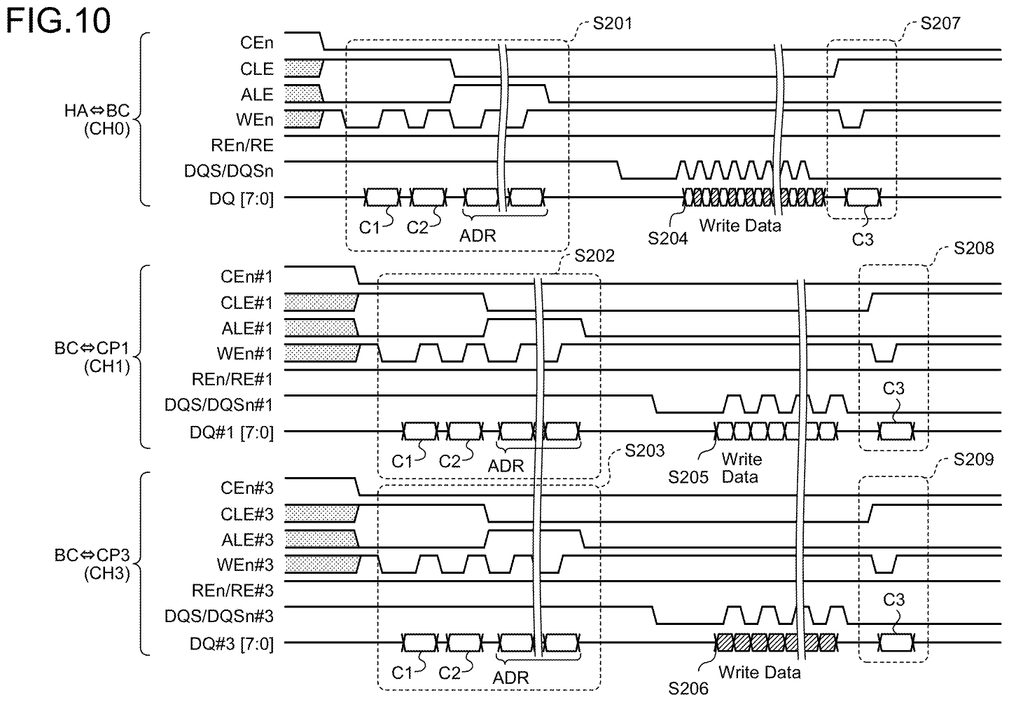

FIG. 10 is a timing chart illustrating various signal waveforms in a write operation by the memory system SYS in the first embodiment. In FIG. 10, the transfer-rate scale factor 116 is set to two and a memory chip CP1 connected to the channel CH1 and a memory chip CP3 connected to the channel CH3 are subjected to a write operation, as an example. A series of operations illustrated in FIG. 10 is executed in the non-bridge control mode of the bridge chip BC. FIG. 10 omits illustrating the bridge chip enable signal BRG_CEn.

At the start of a write operation, the host HA transmits a data input command in an active state of the chip enable signal CEn (S201). Specifically, the host HA transmits a command value C1 indicating a page type, a command value C2 serving as a notice about transmission of write data, and an address value ADR indicating a write location in this order.

In this example, the memory chips CP are configured to be able to store data of multiple pages per a word line. The page type represents any of the pages stored in a single word line. For example, three-page data can be stored in a single word line. In this case the three pages are referred to as an upper page, a middle page, and a lower page. The command C1 indicates, for example, any of an upper page, a middle page, and a lower page.

To store a plurality of pages of data in a single word line, the memory chip CP writes data to the word line after receiving all the pages of data to be written to the same word line. In such a case, the host HA repeatedly transmits data input commands and write data for all the pages of data to be stored in one word line. FIG. 10 illustrates a last one of the operations that the host HA repeatedly executes twice or more to transmit data input commands and write data.

In transmitting the command value C1 and the command value C2, the host HA maintains the command-latch enable signal CLE in an active state (H-level) and toggles the write enable signal WEn. In transmitting the address value ADR, the host HA maintains the address-latch enable signal ALE in an active state (H-level) and toggles the write enable signal WEn.

The bridge chip BC receives and transfers the data input command to the two memory chips CP in parallel via the channel CH1 and the channel CH3 (S202, S203).

After completion of transmitting the data input command, the host HA transmits the write data (S204). The host HA transmits the write data at a frequency twice higher than the transfer frequency of one NAND-side channel. In transmitting the write data, the host HA toggles the data strobe signal DQS/DQSn.

Upon receiving the write data from the host HA, the partial circuit 201 of the bridge chip BC splits the write data into two pieces of write data by sorting the write data into two on a byte basis. The bridge chip BC transmits one of the two pieces of write data to the memory chip CP1 being a write target connected to the channel CH1 via the channel CH1 (S205). The bridge chip BC also transmits the other of the two pieces of write data to the memory chip CP3 being a write target connected to the channel CH3 via the channel CH3 (S206). For example, in FIG. 10, among the write data received from the host-side channel in S204, the data indicated by non-hatching is transferred to the channel CH1, and the data indicated by hatching is transferred to the channel CH3. In S205 and S206 the bridge chip BC transfers the split write data at half the transfer frequency of the write data received in S204. The bridge chip BC executes the operations of S205 and S206 in parallel.

Subsequently, the host HA transmits a command value C3 for instructing as to start of a write operation (S207). In transmitting the command value C3, the host HA maintains the command-latch enable signal CLE in an active state (H-level) and toggles the write enable signal WEn.

The bridge chip BC receives and transfers the command value C3 to the memory chips CP1 and CP3 as write targets in parallel (S208, S209). In response to receipt of the command value C3, the two memory chips CP1 and CP3 controls their respective word lines to write the write data.

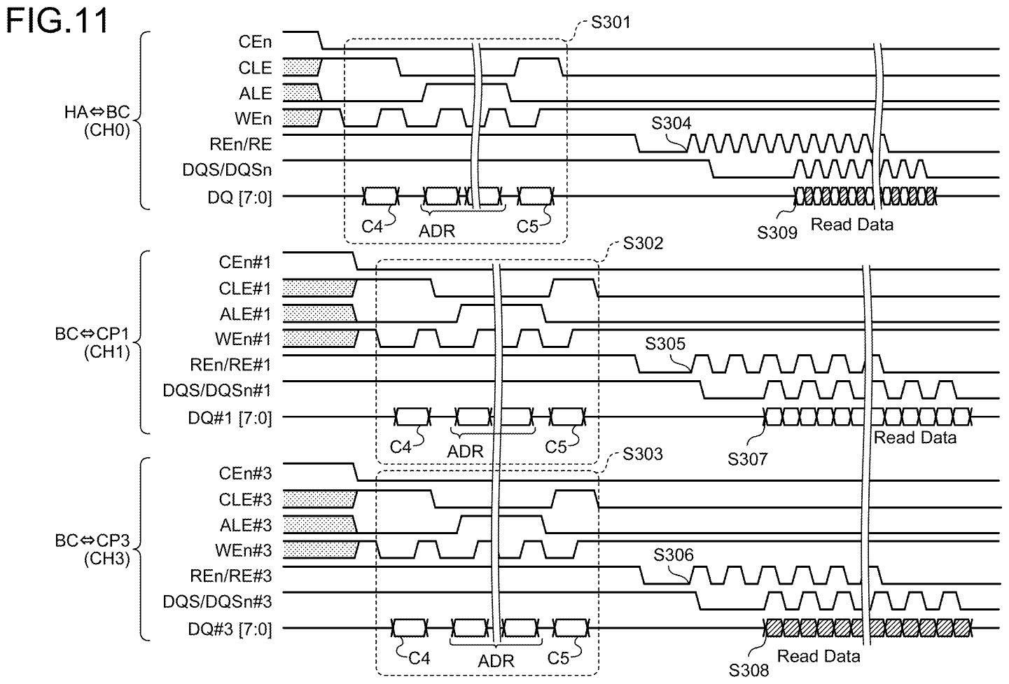

FIG. 11 is a timing chart illustrating various signal waveforms in a read operation by the memory system SYS in the first embodiment. In FIG. 11, the transfer-rate scale factor 116 is set to two and a memory chip CP1 connected to the channel CH1 and a memory chip CP3 connected to the channel CH3 are subjected to a read operation. A series of operations illustrated in FIG. 11 is executed in the non-bridge control mode of the bridge chip BC. FIG. 11 omits illustrating the bridge chip enable signal BRG_CEn.

In a read operation, the host HA transmits a data output command in the active state of the chip enable signal CEn (S301). In S301, the host HA transmits a command value C4 of a command value pair C4 and C5 indicating data output commands, an address value ADR indicating a head position of data to be output, and the command value C5 in this order. In transmitting the command values C4 and C5, the host HA maintains the command-latch enable signal CLE in an active state (H-level) and toggles the write enable signal WEn. In transmitting the address value ADR, the host HA maintains the address-latch enable signal ALE in an active state (H-level) and toggles the write enable signal WEn.

The bridge chip BC receives and transfers the data output command to the two memory chips CP in parallel via the channel CH1 and the channel CH3 (S302, S303).

Subsequently, the host HA starts toggling the read enable signal REn/RE (S304). The host HA toggles the read enable signal REn/RE at a frequency twice higher than the read enable signal REn/RE transferred through the NAND-side channel.

In response to the start of toggling of the read enable signal REn/RE of the channel CH0, the bridge chip BC starts toggling the read enable signals REn/RE of the channel CH1 and the channel CH3 (S305, S306).

After toggling the read enable signals REn/RE, the memory chip CP1 and the memory chip CP3 being read targets connected to the channel CH1 and the channel CH3, respectively, starts outputting read data (S307, S308). To output the read data, the memory chip CP1 and the memory chip CP3 both toggle the data strobe signals DQS/DQSn. The memory chip CP1 and the memory chip CP3 toggle the data strobe signals DQS/DQSn at the same frequency as the read enable signal REn/RE as received.

The bridge chip BC receives read data in parallel from the two memory chips CP1 and CP3 being read targets. In the bridge chip BC, the partial circuit 202 concatenates the two pieces of read data. The bridge chip BC transmits the concatenated read data to the host HA at a frequency twice higher than the data transfer frequency of one NAND-side channel (S309). In transmitting the read data, the bridge chip BC toggles the data strobe signal DQS/DQSn.

In the example described above, the transfer-rate scale factor 116 is set while the bridge chip BC is in the bridge control mode. The bridge chip BC may be configured to allow the transfer-rate scale factor 116 to be set in the non-bridge control mode.

In the above example, the bridge chip BC switches between the bridge control mode and the non-bridge control mode by the bridge chip enable signal BRG_CEn. The switching between the bridge control mode and the non-bridge control mode may not be made by the bridge chip enable signal BRG_CEn. For example, the bridge chip BC may switch between the bridge control mode and the non-bridge control mode by a particular command from the host HA. In such a case, the channel CH0 may not include the signal line for transferring the bridge chip enable signal BRG_CEn.

In the example described above, the host-side channel and the NAND-side channels all have an 8-bit bus width. The host-side channel and the NAND-side channels may have different bit widths.

When the host-side channel and each of the NAND-side channels are different in bus width from each other, the splitter/concatenator circuit 112 receives and sequentially sorts data from the host-side channel into N pieces in units of bus-width of the host-side channel to split the data into N pieces and outputs the N pieces of data in parallel. The splitter/concatenator circuit 112 sets the transfer rate of each piece of divisional data to 1/N of the transfer rate of the data before the division. Upon receiving the N pieces of data in parallel from the N different NAND-side channels, the splitter/concatenator circuit 112 concatenates the N pieces of data into one piece by acquiring and concatenating the N pieces of data in units of bus width of the host-side channel, and outputs the concatenated data. The splitter/concatenator circuit 112 sets the transfer rate of the concatenated data to N times higher than the transfer rate of each of the N pieces of data before concatenating.

As described above, according to the first embodiment, upon receiving data via the host-side channel at the transfer rate N times higher than the transfer rate of the NAND-side channels, the bridge chip BC splits the data into N pieces of data by sorting the data into N pieces in units of bus width of the host-side channel and transmits the N pieces of divisional data to the memory chip group CP in parallel via the different NAND-side channels. Also, upon receiving N pieces of data in parallel from the N NAND-side channels, the bridge chip BC generates a single piece of data by sequentially concatenating the N pieces of data in units of bus width of the host-side channel, and transmits the single piece of data to the host HA via the host-side channel at the transfer rate N times higher than the transfer rate per NAND-side channel.

Thereby, the semiconductor memory device 1 can input and output data at a higher transfer rate.

For comparison with the first embodiment, it is conceivable that when receiving data from the host, the bridge chip splits the data into N pieces by sorting the data into N pieces in units of a page, or when receiving N pieces of data from different NAND-side channels, the bridge chip acquires and concatenates the N pieces of data in units of a page. Such a case will be referred to as a comparative example. According to the comparative example, in order to sort or concatenate data in units of a page, the bridge chip includes a buffer which can temporarily store therein transfer data having a size of at least one or more pages.

To the contrary, according to the first embodiment, the bridge chip BC sorts and concatenates data in units of bus width of the host-side channel. Thus, the bridge chip BC can decrease the buffer capacity to temporarily store transfer data, as compared with the comparative example.

In another point of view, according to the comparative example, in a write operation the bridge chip waits for outputting data of an initial page until the data from the host is accumulated to one-page size in the buffer.

To the contrary, according to the first embodiment, upon receiving data from the host, the bridge chip BC can start outputting the data before the data is accumulated to one-page size.

Further, according to the first embodiment the bridge chip BC is configured to allow the host HA to set the value N as the transfer-rate scale factor 116.

Thus, the semiconductor memory device 1 is variable in terms of the transfer rate for inputting and outputting data.

The bridge chip BC may be configured to be able to change the number of streams of data transfer in a write operation and in a read operation. For example, when receiving data via the host-side channel at the transfer rate N times higher than the transfer rate per NAND-side channel, the bridge chip BC splits the data into N pieces of data by sorting the data into N pieces in units of bus width of the host-side channel and transmits the N pieces of divisional data to the memory chip group CP in parallel via the different NAND-side channels. When receiving L pieces of data in parallel from L NAND-side channels where L is a natural number of two or more and M or less and is different from N, the bridge chip BC generates a single piece of data by concatenating the L pieces of data in units of bus width of the host-side channel and transmits one piece of data to the host HA via the host-side channel at the transfer rate L times higher than the transfer rate per NAND-side channel.

### Second Embodiment

According to the first embodiment, the splitter/concatenator circuit 112 receives data via the host-side channel, and splits the data into a plurality of pieces by sequentially sorting the data to a plurality of channels in units of transfer.

In a second embodiment, upon receipt of data from a host-side channel, a splitter/concatenator circuit (splitter/concatenator circuit 112a) splits the data into N pieces in units of bit width smaller than the bus width of the host-side channel. For example, if the host-side channel has an 8-bit bus width, a bridge chip (bridge chip BCa) receives a data signal DQ in units of 8-bit string aligned along the bus width. The splitter/concatenator circuit 112a splits an 8-bit string aligned along the bus width into N pieces. The splitter/concatenator circuit 112a receives and splits data from the host-side channel into N pieces of data by splitting the data signal DQ[7:0] being an 8-bit string aligned along the bus width. Such a method of splitting data from the host-side channel into N pieces by splitting each bit string aligned along the bus width upon receipt from the host-side channel will be referred to as a space division method.

The following will describe a memory system SYSa of the second embodiment. The same or like elements as those of the memory system SYS of the first embodiment are denoted by the same names and reference signs as the first embodiment. The same or like elements as those of the memory system SYS of the first embodiment will be briefly described or a description thereof will be omitted.

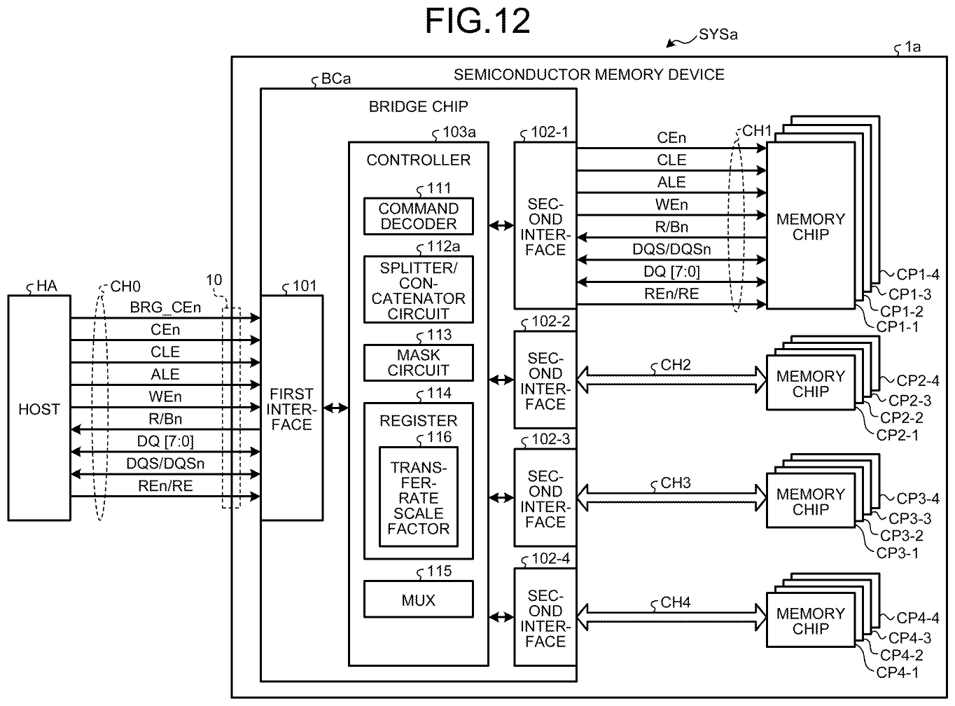

FIG. 12 is a schematic diagram illustrating an exemplary configuration of the memory system SYSa according to the second embodiment.

The memory system SYSa includes a host HA and a semiconductor memory device 1a. The semiconductor memory device 1a includes a bridge chip BCa and a plurality of memory chips CP. In the example illustrated in FIG. 12, the semiconductor memory device 1a includes 16 memory chips CP.

The bridge chip BCa is electrically connected between an external terminal group 10 and M channels (herein, as an example, four channels CH1, CH2, CH3, and CH4). The external terminal group 10 is electrically connected to the host HA via the channel CH0.

The 16 memory chips CP are connected to the bridge chip BCa via the channels CH1, CH2, CH3, and CH4, as in the first embodiment.

The configurations of the channels CH0, CH1, CH2, CH3, and CH4 are identical to those in the first embodiment.

The bridge chip BCa includes a first interface 101, four second interfaces 102, and a controller 103a. The controller 103a includes a command decoder 111, a splitter/concatenator circuit 112a, a mask circuit 113, a register 114, and a multiplexer (MUX) 115. A transfer-rate scale factor 116 is set to the register 114.

Upon receipt of data from the host HA, the splitter/concatenator circuit 112a splits the data into the number of pieces indicated by the transfer-rate scale factor 116, and upon receipt of data via the number of NAND-side channels indicated by the transfer-rate scale factor 116, the splitter/concatenator circuit 112a concatenates data into the number of pieces indicated by the transfer-rate scale factor 116. The splitter/concatenator circuit 112a transfers the data via the host-side channel at the transfer rate corresponding to the transfer-rate scale factor 116. Thereby, in the second embodiment the bridge chip BCa can perform data transfer, as described with reference to FIG. 2 to FIG. 4.

Among the signal line group constituting the host-side channel, the signal lines for transferring the data signal DQ[7:0] are exemplary signal lines for data transfer. The read enable signal REn/RE and the data strobe signal DQS/DQSn transferred through the host-side channel are exemplary control signals serving to control data signals DQ[7:0] in the signal lines. Among the signal line group constituting the host-side channel, the set of signal lines for transferring the read enable signal REn/RE and for transferring the data strobe signal DQS/DQSn is an exemplary signal line group for transferring control signals serving to control data transfer in the signal lines for transferring the data signal DQ[7:0]. The command-latch enable signal CLE, the address-latch enable signal ALE, and the write enable signal WEn are exemplary control signals serving to control command and address transfer in the signal lines for transferring the data signal DQ[7:0]. Among the signal line group constituting the host-side channel, the set of signal lines for transferring the command-latch enable signal CLE, for transferring the address-latch enable signal ALE, and for transferring the write enable signal WEn is an exemplary signal line group for transferring control signals serving to control command and address transfer in the signal lines for transferring the data signal DQ[7:0].

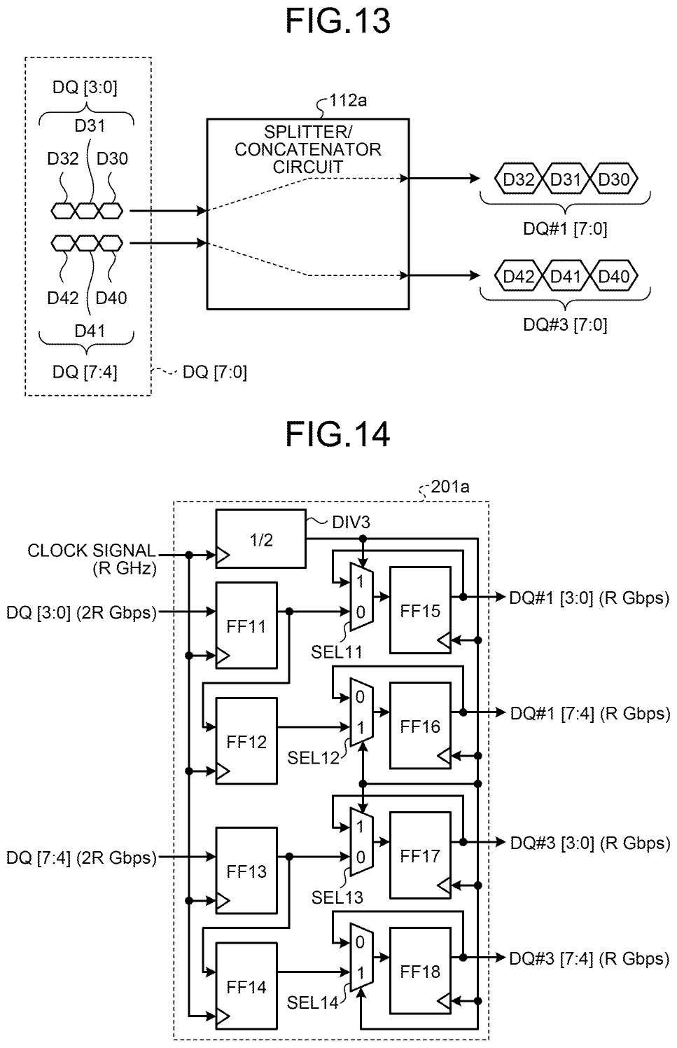

FIG. 13 is a schematic diagram for explaining a data splitting method by a splitter/concatenator circuit 112a of the second embodiment. In FIG. 13, the transfer-rate scale factor 116 is set to two and the channel CH1 and the channel CH3 are selected as data transfer paths by way of example.

The splitter/concatenator circuit 112a splits data from the host HA into two pieces by the space division method and outputs each piece of divisional data at the same bit width as that for data transfer in the NAND-side channels.

In the example illustrated in FIG. 13, data signals DQ[7:0] are received from the host-side channel, and the splitter/concatenator circuit 112a converts a 4-bit width of data D30, D31, and D32 being a data signal DQ[3:0] of the data signals DQ[7:0] to an 8-bit width equal to the bus width of the NAND-side channels. The splitter/concatenator circuit 112a outputs the data string D30, D31, and D32 at an 8-bit width. The data string D30, D31, and D32 output from the splitter/concatenator circuit 112a is transferred, for example, through the channel CH1 as the data signal DQ #1[7:0].

Further, among the data signals DQ[7:0] received from the host-side channel, the splitter/concatenator circuit 112a converts a 4-bit width of data D40, D41, and D42 being a data signal DQ[7:4] to an 8-bit width equal to the bus width of the NAND-side channels. The splitter/concatenator circuit 112a outputs a data string D40, D41, and D42 at an 8-bit width. The data string D40, D41, and D42 output from the splitter/concatenator circuit 112a is transferred, for example, through the channel CH3 as a data signal DQ #3[7:0].

The splitter/concatenator circuit 112a receives data from the host HA at a transfer rate twice higher than the transfer rate of one NAND-side channel. The splitter/concatenator circuit 112a outputs each of two data strings at half the transfer frequency of the input data signal DQ[7:0].

In this manner, the splitter/concatenator circuit 112a splits the data received via the host-side channel into two pieces by the space division method.

At the transfer-rate scale factor 116 being 3 or more, the splitter/concatenator circuit 112 can also split the data received from the host-side channel by the number indicated by the transfer-rate scale factor 116 by the space division method, as described above.

For example, at the transfer-rate scale factor 116 being 4, the splitter/concatenator circuit 112a outputs a bit string of a data signal DQ[1:0], a bit string of a data signal DQ[3:2], a bit string of a data signal DQ[5:4], and a bit string of a data signal DQ[7:6] in units of 8-bit width, among the data signals DQ[7:0] received via the host-side channel.

For another example, at the transfer-rate scale factor 116 being 3, the splitter/concatenator circuit 112a outputs a bit string of a data signal DQ[2:0], a bit string of a data signal DQ[5:3], and a bit string of a data signal DQ[7:6] in units of 8-bit width, among the data signals DQ[7:0] received via the host-side channel. The division ratio of the bit width of the data signal DQ[7:0] received via the host-side channel at the transfer-rate scale factor 116 being 3 is not limited to such examples.

In this manner, the splitter/concatenator circuit 112a splits the data, upon receipt via the host-side channel, into a plurality of pieces by the space division method. This allows use of the host-side channel as N communication paths (i.e. N streams) having a bus width smaller than the bus width of the host-side channel.

To be able to deal with any of the transfer-rate scale factors 116 of 2, 3, and 4, the splitter/concatenator circuit 112a may include, for example, a partial circuit for splitting data received via the host-side channel into two pieces, a partial circuit for splitting the data received via the host-side channel into three pieces, and a partial circuit for splitting the data received via the host-side channel into four pieces.

As an example, FIG. 14 illustrates an exemplary configuration of a partial circuit 201a included in the splitter/concatenator circuit 112a for splitting the data received via the host-side channel into two pieces. In the example illustrated in FIG. 14, the partial circuit 201a includes a ½ frequency divider DIV3, eight flip-flops FF11, FF12, FF13, FF14, FF15, FF16, FF17, and FF18, and four selectors SEL11, SEL12, SEL13, and SEL14.

A clock signal having a certain frequency is input in common to a clock input terminal of the ½ frequency divider DIV3, a clock input terminal of the flip-flop FF11, a clock input terminal of the flip-flop FF12, a clock input terminal of the flip-flop FF13, and a clock input terminal of the flip-flop FF14. Referring to FIG. 14, the clock signal is referred to as an input clock. The input clock may be generated from the strobe signal (data strobe signal DQS or read enable signal REn) from the host HA or may be a clock signal generated inside the controller 103. The frequency of the input clock is defined to be R[GHz].

The ½ frequency divider DIV3 outputs a clock signal obtained by dividing the frequency of the input clock in half. In FIG. 14, the clock signal output from the ½ frequency divider DIV3 will be referred to as a frequency-divided clock. The frequency-divided clock is input in common to a selection-signal input terminal of the selector SEL11, a selection-signal input terminal of the selector SEL12, a selection-signal input terminal of the selector SEL13, a selection-signal input terminal of the selector SEL14, a clock input terminal of the flip-flop FF15, a clock input terminal of the flip-flop FF16, a clock input terminal of the flip-flop FF17, and a clock input terminal of the flip-flop FF18.

Among the data signals DQ[7:0] received at the transfer rate 2R[Gbps] from the host-side channel, the data signal DQ[3:0] is input to a D-input terminal of the flip-flop FF11. A Q-output terminal of the flip-flop FF11 is connected to a D-input terminal of the flip-flop FF12. Thus, the flip-flop FF12 can acquire the data acquired by the flip-flop FF11 with a delay by one clock of the input clock from the flip-flop FF11.

Among the data signals DQ[7:0] received at the transfer rate 2R[Gbps] from the host-side channel, the data signal DQ[7:4] is input to a D-input terminal of the flip-flop FF13. A Q-output terminal of the flip-flop FF13 is connected to a D-input terminal of the flip-flop FF14. Thus, the flip-flop FF14 can acquire the data acquired by the flip-flop FF13 with a delay by one clock of the input clock from the flip-flop FF13.

The Q-output terminal of the flip-flop FF11 is further connected to one of two input terminals of the selector SEL11. The Q-output terminal of the flip-flop FF12 is connected to one of two input terminals of the selector SEL12. The Q-output terminal of the flip-flop FF13 is further connected to one of two input terminals of the selector SEL13. The Q-output terminal of the flip-flop FF14 is connected to one of two input terminals of the selector SEL14.

An output terminal of the selector SEL11 is connected to a D-input terminal of the flip-flop FF15. A Q-output terminal of the flip-flop FF15 is connected to the other of the two input terminals of the selector SEL11.

In response to the frequency-divided clock indicating zero, the selector SEL11 outputs the signal input from the Q-output terminal of the flip-flop FF11. In response to the frequency-divided clock indicating 1, the selector SEL11 outputs the signal input from the Q-output terminal of the flip-flop FF15.

An output terminal of the selector SEL12 is connected to a D-input terminal of the flip-flop FF16. A Q-output terminal of the flip-flop FF16 is connected to the other of the two input terminals of the selector SEL12.

In response to the frequency-divided clock indicating zero, the selector SEL12 outputs the signal input from the Q-output terminal of the flip-flop FF16. In response to the frequency-divided clock indicating 1, the selector SEL12 outputs the signal input from the Q-output terminal of the flip-flop FF12.

An output terminal of the selector SEL13 is connected to a D-input terminal of the flip-flop FF17. A Q-output terminal of the flip-flop FF17 is connected to the other of the two input terminals of the selector SEL13.

In response to the frequency-divided clock indicating zero, the selector SEL13 outputs the signal input from the Q-output terminal of the flip-flop FF13. In response to the frequency-divided clock indicating 1, the selector SEL13 outputs the signal input from the Q-output terminal of the flip-flop FF17.

An output terminal of the selector SEL14 is connected to a D-input terminal of the flip-flop FF18. A Q-output terminal of the flip-flop FF18 is connected to the other of the two input terminals of the selector SEL14.

In response to the frequency-divided clock indicating zero, the selector SEL14 outputs the signal input from the Q-output terminal of the flip-flop FF18. In response to the frequency-divided clock indicating 1, the selector SEL14 outputs the signal input from the Q-output terminal of the flip-flop FF14.

As configured as above, among the data signals DQ[7:0] input from the host HA, the partial circuit 201a can output the data as the data signal DQ[3:0] having an 8-bit width in total at the transfer rate R[Gbps] from the Q-output terminal of the flip-flop FF15 and the Q-output terminal of the flip-flop FF16. The data is output from the Q-output terminal of the flip-flop FF15 and the Q-output terminal of the flip-flop FF16 and received as the data signal DQ #1[7:0] at, for example, the channel CH1. Also, among the data signals DQ[7:0] input from the host HA, the partial circuit 201a can output the data as the data signal DQ[7:4] having an 8-bit width in total at the transfer rate R[Gbps] from the Q-output terminal of the flip-flop FF17 and the Q-output terminal of the flip-flop FF18. The data is output from the Q-output terminal of the flip-flop FF17 and the Q-output terminal of the flip-flop FF18 and received, for example, at the channel CH3 as the data signal DQ #3[7:0].

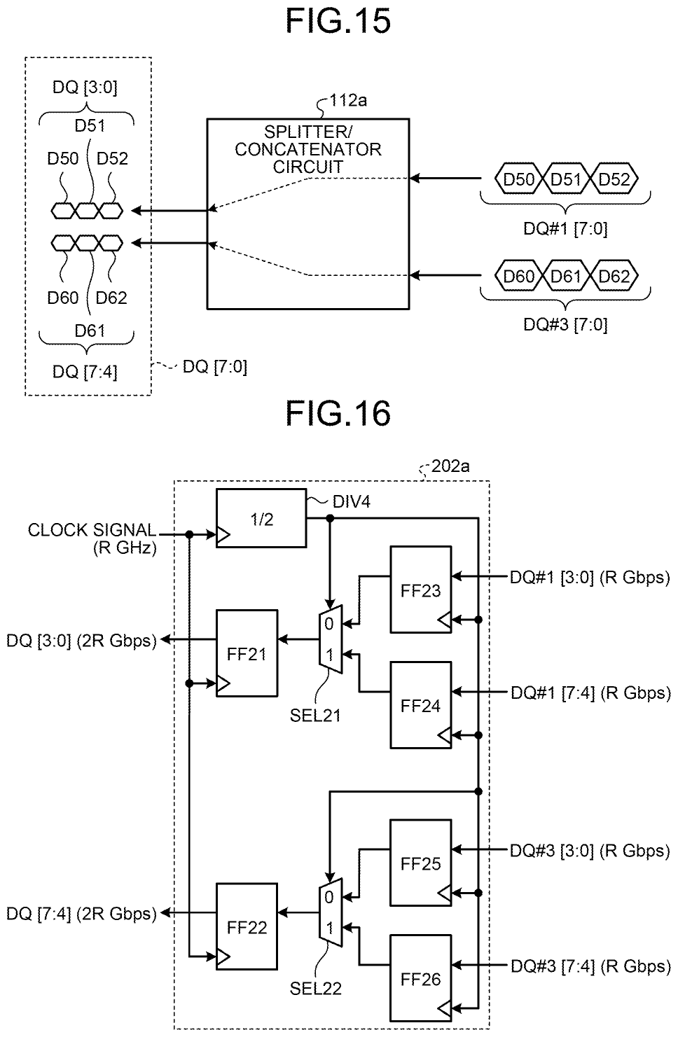

FIG. 15 is a schematic diagram for explaining a data concatenating method by the splitter/concatenator circuit 112a of the second embodiment. In FIG. 15, the transfer-rate scale factor 116 is set to two and the channel CH1 and the channel CH3 are selected as data transfer paths by way of example.

The splitter/concatenator circuit 112a receives data via the channel CH1 and data via the channel CH3 and concatenates the two pieces of data along the bit-width for output. Before data concatenating, the splitter/concatenator circuit 112a converts the bit widths of the two pieces of data such that the bit width after data concatenating matches the bit width of transfer in the host-side channel.

In the example illustrated in FIG. 15, the splitter/concatenator circuit 112a receives a data string D50, D51, and D52 as the data signal DQ #1[7:0] from the channel CH1, and a data string D60, D61, and D62 as the data signal DQ #3[7:0] from the channel CH3. In such a case, the splitter/concatenator circuit 112a converts the bit width of each of the data string D50, D51, and D52 and the data string D60, D61, and D62 from 8 bits to 4 bits. The splitter/concatenator circuit 112a concatenates the data string D50, D51, and D52 and the data string D60, D61, and D62 along the bit width and outputs the data as the data signal DQ[7:0] to be supplied to the host-side channel. Specifically, the data string D50, D51, and D52 is transferred to the host HA as the data signal [3:0] among the data signals DQ[7:0], and the data string D60, D61, and D62 is transferred to the host HA as the data signal [7:4] among the data signals DQ[7:0].

The splitter/concatenator circuit 112a outputs the concatenated data string at a transfer rate twice higher than the transfer rate of one NAND-side channel. In this example, to heighten the transfer rate of the concatenated data string to twice the transfer rate of one NAND-side channel, the splitter/concatenator circuit 112a outputs the concatenated data string at a transfer frequency twice higher than the transfer frequency of the input data signal DQ #1[7:0] and data signal DQ #3[7:0].

In this manner, the splitter/concatenator circuit 112a receives the two or more pieces of data in parallel from the two or more NAND-side channels and concatenates them along the bit width for output.

At the transfer-rate scale factor 116 being 3 or more, the splitter/concatenator circuit 112a can also generate a single data string by concatenating the number of pieces of data indicated by the transfer-rate scale factor 116, as described above.

The splitter/concatenator circuit 112a may include individual partial circuits that concatenate a plurality of pieces of data into one piece, corresponding to values of the number of settable combinations of data. For example, to be able to deal with any of the transfer-rate scale factors 116 of 2, 3, and 4, the splitter/concatenator circuit 112a may include a partial circuit, for concatenating two pieces of data received via different NAND-side channels, a partial circuit for concatenating three pieces of data received via different NAND-side channels, and a partial circuit for concatenating four pieces of data received via different NAND-side channels.

As an example, FIG. 16 illustrates an exemplary configuration of a partial circuit 202a included in the splitter/concatenator circuit 112a for concatenating two pieces of data received via different NAND-side channels. In the example illustrated in FIG. 16, the partial circuit 202a includes a ½ frequency divider DIV4, flip-flops FF21, FF22, FF23, FF24, FF25, and FF26, and selectors SEL21 and SEL22.

A clock signal having a certain frequency is input in common to a clock input terminal of the ½ frequency divider DIV4, a clock input terminal of the flip-flop FF21, and a clock input terminal of the flip-flop FF22. In FIG. 16, the clock signal is referred to as an input clock. The input clock may be generated from the strobe signal (data strobe signal DQS or read enable signal REn) input from the host HA or may be a clock signal generated inside the controller 103. The frequency of the input clock is defined to be R[GHz].

The ½ frequency divider DIV4 outputs a clock signal obtained by dividing the frequency of the input clock in half. In FIG. 16, the clock signal output from the ½ frequency divider DIV4 will be referred to as a frequency-divided clock. The frequency-divided clock is input in common to a selection-signal input terminal of the selector SEL21, a clock input terminal of the flip-flop FF23, a clock input terminal of the flip-flop FF24, a clock input terminal of the flip-flop FF25, and a clock input terminal of the flip-flop FF26.

Among the data signals DQ #1[7:0] having an 8-bit width received at the transfer rate R[Gbps] from the channel CH1, the data signal DQ #1[3:0] is input to a D-input terminal of the flip-flop FF23. A Q-output terminal of the flip-flop FF23 is connected to one of two input terminals of the selector SEL21.

Among the 8-bit-width data signals DQ #1[7:0] received at the transfer rate R[Gbps] from the channel CH1, the data signal DQ #1[7:4] is input to a D-input terminal of the flip-flop FF24. A Q-output terminal of the flip-flop FF24 is connected to the other of the two input terminals of the selector SEL21.

In response to the frequency-divided clock indicating zero, the selector SEL21 outputs the signal input from the Q-output terminal of the flip-flop FF23. In response to the frequency-divided clock indicating 1, the selector SEL21 outputs the signal input from the Q-output terminal of the flip-flop FF24.

An output terminal of the selector SEL21 is connected to a D-input terminal of the flip-flop FF21. Thus, the Q-output terminal of the flip-flop FF21 can output the data as the data signal DQ #1[7:0] at a 4-bit width and at a transfer frequency twice higher than the transfer frequency of the data signal DQ #1[7:0].

Among the 8-bit-width data signals DQ #3[7:0] received at the transfer rate R[Gbps] from the channel CH3, the data signal DQ #3[3:0] is input to a D-input terminal of the flip-flop FF25. A Q-output terminal of the flip-flop FF25 is connected to one of two input terminals of the selector SEL22.

Among the 8-bit-width data signals DQ #3[7:0] received at the transfer rate R[Gbps] from the channel CH3, the data signal DQ #3[7:4] is input to a D-input terminal of the flip-flop FF26. A Q-output terminal of the flip-flop FF26 is connected to the other of the two input terminals of the selector SEL22.

In response to the frequency-divided clock indicating zero, the selector SEL22 outputs the signal input from the Q-output terminal of the flip-flop FF25. In response to the frequency-divided clock indicating 1, the selector SEL22 outputs the signal input from the Q-output terminal of the flip-flop FF26.

An output terminal of the selector SEL26 is connected to a D-input terminal of the flip-flop FF22. Thus, the Q-output terminal of the flip-flop FF22 can output the data as the data signal DQ #3[7:0] at a 4-bit width and at a transfer frequency twice higher than the transfer frequency of the data signal DQ #3[7:0].

The data is output from the Q-output terminal of the flip-flop FF21 to the host HA as the data signal DQ[3:0]. The data is output from the Q-output terminal of the flip-flop FF22 to the host HA as the data signal DQ[7:4]. Thus, the partial circuit 202a can concatenate the two pieces of data, upon receipt from the different NAND-side channels at the transfer rate R[Gbps], into one piece and output the concatenated data at the bus width of the host-side channel at the transfer rate 2R[Gbps].

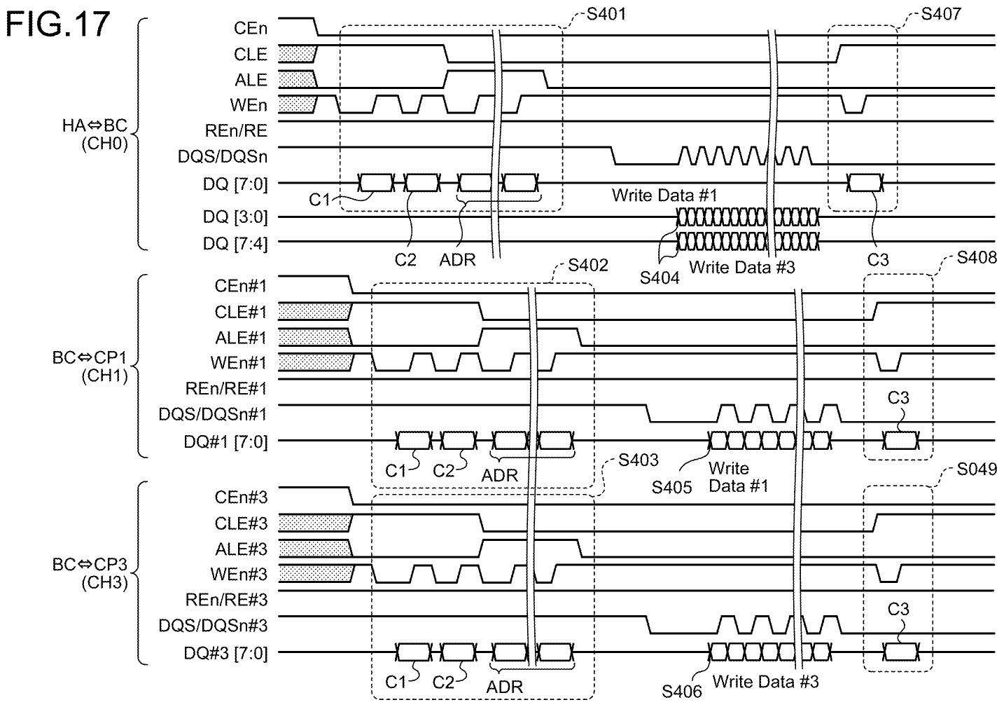

FIG. 17 is a timing chart illustrating various signal waveforms in a write operation of the memory system SYSa according to the second embodiment. In FIG. 17, the transfer-rate scale factor 116 is set to two and a memory chip CP1 connected to the channel CH1 and a memory chip CP3 connected to the channel CH3 are subjected to a write operation, by way of example. A series of operations illustrated in FIG. 17 is executed while the bridge chip BCa is maintained in the non-bridge control mode. FIG. 17 omits illustrating the bridge chip enable signal BRG_CEn.

First, the host HA transmits a data input command in the active state of the chip enable signal CE (S401). The configuration of the data input command is identical to that of the first embodiment.

The bridge chip BCa receives and transmits in parallel the data input command to the memory chip CP1 and the memory chip CP3 being write targets (S402, S403).

After completion of transmitting the data input command, the host HA transmits write data (S404). Herein, the host HA transmits write data #1 as the data signal DQ[3:0] to the memory chip CP1 and transmits write data #3 as the data signal DQ[7:4] to the memory chip CP3. The host HA transmits the write data #1 and the write data #3 in parallel and synchronously. The host HA transmits the data signal DQ[7:0] at the transfer frequency twice higher than the transfer frequency of the data signal DQ[7:0] in the NAND-side channel.

The bridge chip BCa receives the write data #1 and the write data #3 from the host HA, and the partial circuit 201a converts the write data #1 and the write data #3 from a 4-bit width to a 8-bit width. The bridge chip BCa transmits the write data #1 as the data signal DQ #1[7:0] to the memory chip CP1 being a write target (S405). In addition, the bridge chip BCa transmits the write data #3 as the data signal DQ #3[7:0] to another memory chip CP3 being a write target (S406). The bridge chip BCa executes operations in S405 and S406 in parallel. The transfer frequency of each of the data signal DQ #1[7:0] and the data signal DQ #3[7:0] is half the transfer frequency of the data signal DQ[7:0].

The host HA transmits a command value C3 serving to instruct as to start of a write operation (S407). The bridge chip BCa receives and transmits in parallel the command value C3 to the memory chip CP1 and the memory chip CP3 being write targets (S408, S409). In response to receipt of the command value C3, the memory chip CP1 and the memory chip CP3 control their own word lines to write the received write data thereto.

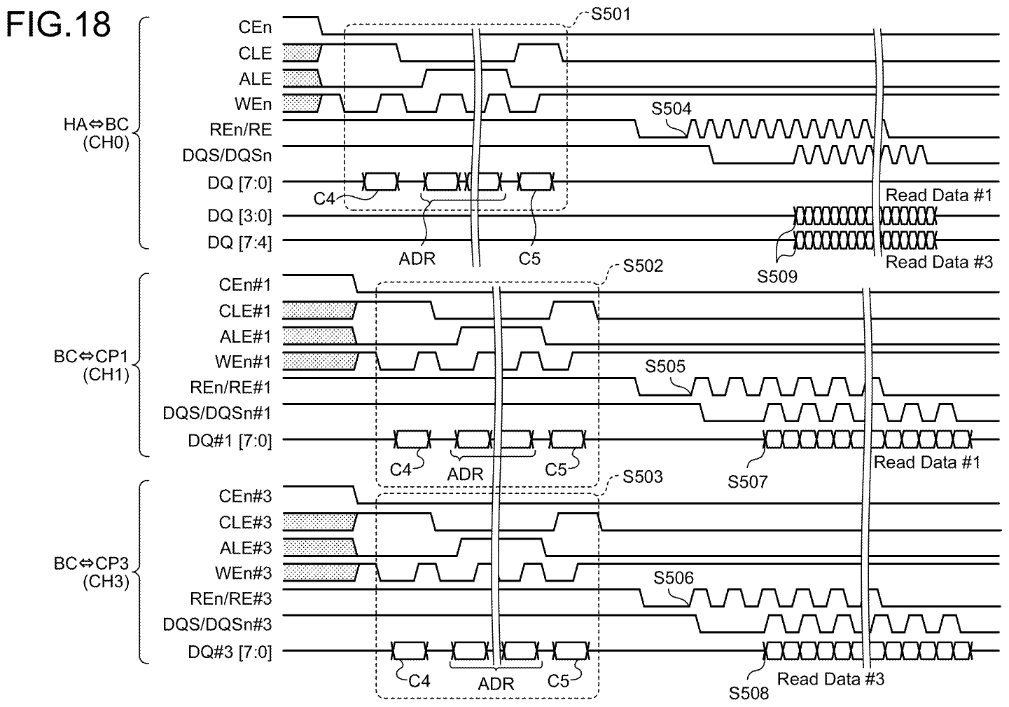

FIG. 18 is a timing chart illustrating various signals waveforms in a read operation of the memory system SYSa according to the second embodiment. In FIG. 18, the transfer-rate scale factor 116 is set to two, and a memory chip CP1 connected to the channel CH1 and a memory chip CP3 connected to the channel CH3 are subjected to a read operation. Also, a series of operations illustrated in FIG. 18 is executed while the bridge chip BCa is maintained in the non-bridge control mode. FIG. 18 omits illustrating the bridge chip enable signal BRG_CEn.

First, the host HA transmits a data output command in the active state of the chip enable signal CEn (S501). The configuration of the data output command is identical to that of the first embodiment.

The bridge chip BCa receives and transmits in parallel the data output command to the memory chip CP1 and the memory chip CP3 being read targets (S502, S503).

The host HA starts toggling the read enable signal REn/RE (S504). The host HA toggles the read enable signal REn/RE at a frequency twice than the read enable signal REn/RE transferred through the NAND-side channel.

In response to the start of toggling of the read enable signal REn/RE in the channel CH0, the bridge chip BCa starts toggling the read enable signals REn/RE in the channel CH1 and the channel CH3 (S505, S506).

After toggling the read enable signals REn/RE, the memory chip CP1 and the memory chip CP3 being read targets both start outputting read data (S507, S508). The two memory chips CP toggle the data strobe signals DQS/DQSn for outputting the read data. The memory chip CP1 and the memory chip CP3 each toggle the data strobe signal DQS/DQSn at the same frequency as the read enable signal REn/RE when received.

The read data output from the memory chip CP1 being a read target will be referred to as read data #1. The read data output from the memory chip CP3 being a read target will be referred to as read data #3.

The bridge chip BCa receives the read data #1 and the read data #3 in parallel. The bridge chip BCa converts the read data #1 and the read data #3 from an 8-bit width to a 4-bit width. The bridge chip BCa concatenates the read data #1 and the read data #3 along the bit width and transmits the concatenated data to the host HA (S509). Specifically, the bridge chip BCa transmits the read data #1 as the data signal DQ[3:0] and the read data #3 as the data signal DQ[7:4] to the host HA in parallel. The bridge chip BCa transmits the data signal DQ[7:0] to the host HA at a frequency twice higher than the data transfer frequency of one NAND-side channel.

According to the second embodiment, thus, when receiving data via the host-side channel at the transfer rate N times higher than the transfer rate per NAND-side channel, the bridge chip BCa splits the data into pieces of data having a bit width smaller than the bus width of the NAND-side channel in units of bus width of the NAND-side channel. Thereby, the bridge chip BCa splits the data, received via the host-side channel, into N pieces of data, converts the bit width of each of the N pieces of data to the same bit width as that of each NAND-side channel, and then transmits the N pieces of data to the memory chip group CP in parallel via the N NAND-side channels. Upon receipt of the N pieces of data in parallel from the N NAND-side channels, the bridge chip BCa converts the bit width of the N pieces of data to the bit width smaller than the bit width of the host-side channel, and concatenates the N pieces of data along the bit width. The bridge chip BCa transmits the concatenated data to the host HA via the host-side channel at the transfer rate N times higher than the transfer rate per NAND-side channel.

Thereby, the semiconductor memory device 1a can input and output data at a higher transfer rate.

Further, in comparison with the comparative example, the bridge chip BCa can decrease the buffer capacity for temporarily storing transfer data.

Unlike the comparative example, in a write operation the bridge chip BCa can start outputting data before the data from the host HA is accumulated to one-page size.

Moreover, according to the second embodiment, the bridge chip BCa is configured to allow the transfer-rate scale factor N to be set from the host HA, as with the first embodiment.

The bridge chip BCa may be configured to be able to differ between a write operation and a read operation in the number of streams of data transfer. Upon receipt of data via the host-side channel at the transfer rate N times higher than the transfer rate per NAND-side channel, the bridge chip BCa split, in units of bus width of the NAND-side channel, the data into pieces of data having a bit width smaller than the bus width of the NAND-side channel. Thereby, the bridge chip BCa splits the data, received via the host-side channel, into N pieces of data, converts the bit width of each of the N pieces of data to the same bit width as that of the bus width per NAND-side channel, and then transmits the N pieces of data to the memory chip group CP in parallel via the N NAND-side channels. Upon receipt of L pieces of data in parallel from L NAND-side channels where L is a natural number of 2 or more and M or less and different from N, the bridge chip BCa converts the bit width of the L pieces of data to the bit width smaller than the bit width of the host-side channel, and concatenates the L pieces of data along the bit width. The bridge chip BCa transmits the concatenated data to the host HA at the transfer rate L times higher than the transfer rate per NAND-side channel via the host-side channel.

The configuration of the memory system SYSa according to the second embodiment can be modified in various manners. The following will describe exemplary modifications of the memory system SYSa of the second embodiment. In the following modification, the differences from the configuration of the memory system SYSa of the second embodiment will be described, and a description of the same or like elements will be omitted.

First Modification

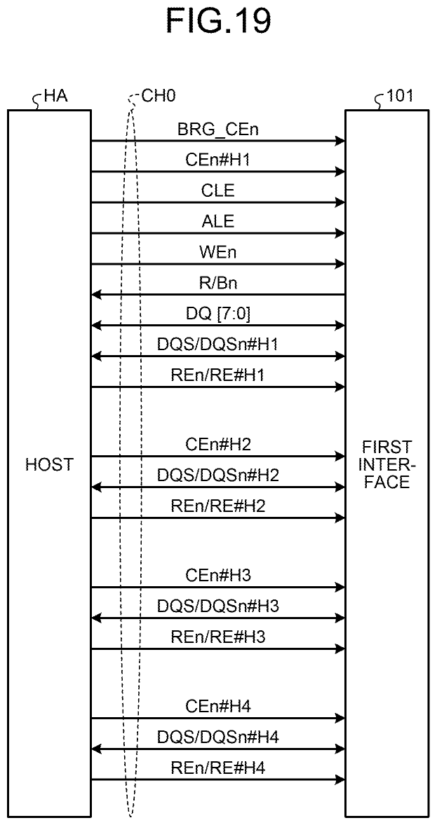

FIG. 19 is a schematic diagram illustrating a configuration of a host-side channel (i.e., channel CH0) according to a first modification of the second embodiment. According to the first modification, the host-side channel includes, for each NAND-side channel, a signal-line set including a signal line for transferring the chip enable signal CEn, signal lines for transferring the data strobe signal DQS/DQSn, and signal lines for transferring the read enable signal REn/RE. The chip enable signal CEn, the data strobe signal DQS/DQSn, and the read enable signal REn/RE transferred in a Z-th signal-line set will be referred to as a chip enable signal CEn #HZ, a data strobe signal DQS/DQSn #HZ, and a read enable signal REn/RE #HZ where Z is a natural number of one to four.

The data strobe signal DQS/DQSn and the read enable signal REn/RE serve as control signals for controlling data transfer through the signal lines in which data signals DQ are transferred. By multiplexing each set of the signal lines for transferring the data strobe signal DQS/DQSn and the signal lines for transferring the read enable signal REn/RE, it is made possible to asynchronously transfer data in the host-side channel through communication paths having a bit width smaller than the bus width of the host-side channel. That is, data may not be transferred through the communication paths in a synchronous manner or data may be transferred in one direction through one communication path while another data is transferred in the other direction through another communication path.

The number of the sets of signal lines for transferring the chip enable signal CEn, the data strobe signal DQS/DQSn, and the read enable signal REn/RE included in the host-side channel may not be equal to M, i.e., the number of the NAND-side channels included in the semiconductor memory device 1a. For example, the number of the sets of signal lines for transferring the chip enable signal CEn, the data strobe signal DQS/DQSn, and the read enable signal REn/RE included in the host-side channel may be defined as K where K is two or more and M or less. At the number K being less than M, a possible maximum value of N is defined as K. That is, the host-side channel can be used as K communication paths at maximum.

At the number K equal to M, M chip enable signals CEn transferred through the host-side channel can be used for selecting the NAND-side channel. In other words, in accordance with the chip enable signal CEn from the host-side channel, the command decoder 111 of the bridge chip BCa can specify the NAND-side channel connected to the memory chip CP as a transfer destination of a command, an address, and data.

When K is less than M, the command decoder 111 can select the NAND-side channel by another method different from the method using the chip enable signal CEn. The command decoder 111 may select the NAND-side channel according to an address received from the host HA. The signal line for transferring the chip enable signal CEn included in the host-side channel may not be multiplexed if the command decoder 111 is configured to be able to select the NAND-side channel by a method different from the method using the chip enable signal CEn.

Herein, K is defined to be equal to M, and the host-side channel includes the signal lines for transferring the chip enable signals CEn in the respective NAND channels, and the command decoder 111 selects one of the NAND-side channels in accordance with the chip enable signal CEn by way of example. Specifically, the chip enable signal CEn #HZ, the data strobe signal DQS/DQSn #HZ, and the read enable signal REn/RE #HZ are associated with a channel CHZ among the four NAND-side channels.

In the first modification of the second embodiment, the bridge chip BCa is capable of transferring data in the manner as described with reference to FIG. 2 to FIG. 4. At the N being two or more, the splitter/concatenator circuit 112a of the bridge chip BCa can asynchronously N streams of data transfer.

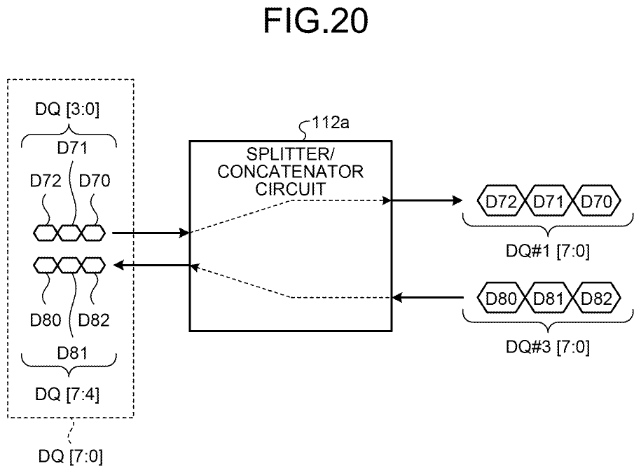

FIG. 20 is a schematic diagram for explaining an operation of the splitter/concatenator circuit 112a according to the first modification of the second embodiment. In FIG. 20, the transfer-rate scale factor 116, i.e., the set value of N is two and the channel CH1 and the channel CH3 are selected as data transfer paths by way of example.

At the transfer-rate scale factor 116 being 2, the signal lines for transferring the data signal DQ[7:0] are used as two communication paths. The data signal DQ[3:0] represents a data signal DQ transferred in one of the two communication paths, and the data signal DQ[7:4] represents a data signal DQ transferred in the other of the two communication paths.

In the example illustrated in FIG. 20, the splitter/concatenator circuit 112a receives the data signal DQ[3:0], i.e., a data string D70, D71, and D72 from the host-side channel. Also, the splitter/concatenator circuit 112a receives the data signal DQ #3[7:0], i.e., a data string D80, D81, and D82 from the channel CH3.

The splitter/concatenator circuit 112a converts the bit width of the data string D70, D71, and D72 from 4 bits to 8 bits and outputs the data at half the transfer frequency at the time of reception. The splitter/concatenator circuit 112a outputs the data string D70, D71, and D72 as the data signal DQ #1[7:0], which is transmitted to the channel CH1.

The splitter/concatenator circuit 112a converts the bit width of the data string D80, D81, and D82 from 8-bits to 4-bits and outputs the data at the transfer frequency twice higher than the transfer frequency at the time of reception. The splitter/concatenator circuit 112a outputs the data string D80, D81, and D82 as the data signal DQ[7:4], which is transmitted to the host-side channel.

The reception period of the data string D70, D71, and D72 from the host-side channel to the splitter/concatenator circuit 112a and the reception period of the data string D80, D81, and D82 from the channel CH3 to the splitter/concatenator circuit 112a may be or may not be overlapped with each other. If the reception periods are overlapped with each other, the splitter/concatenator circuit 112a can concurrently transfer the data string D70, D71, and D72 and the data string D80, D81, and D82.

Likewise, the transfer period of the data string D70, D71, and D72 in the host-side channel and the transfer period of the data string D80, D81, and D82 in the host-side channel may be or may not be overlapped with each other.

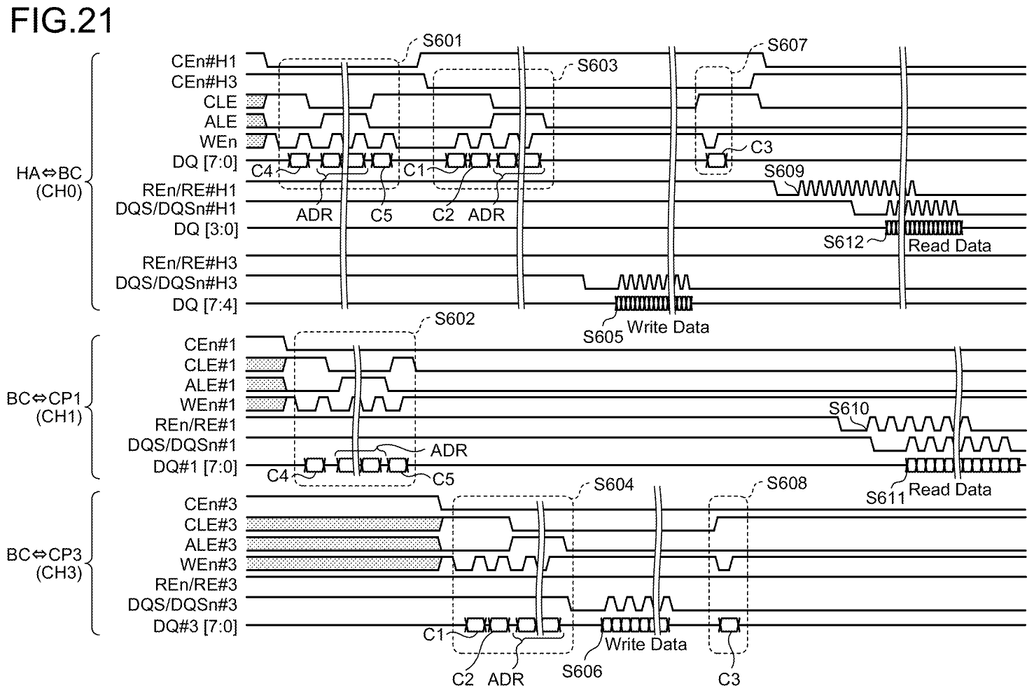

FIG. 21 is a timing chart illustrating various signal waveforms in an operation of the memory system SYSa according to the first modification of the second embodiment. In FIG. 21, the transfer-rate scale factor 116 is set to two, a memory chip CP1 connected to the channel CH1 is subjected to a read operation, and a memory chip CP3 connected to the channel CH3 is subjected to a write operation, by way of example. A series of operations illustrated in FIG. 21 is performed while the bridge chip BCa is maintained in the non-bridge control mode. FIG. 21 omits illustrating the bridge chip enable signal BRG_CEn.

First, the host HA transmits a data output command in the active state of the chip enable signal CEn #H1 (S601). The configuration of the data output command is identical to that of the first embodiment.

From the active state of the chip enable signal CEn #H1 upon reception of the data output command, the bridge chip BCa recognizes that the data output command is addressed to the memory chip CP1 connected to the channel CH1. The bridge chip BCa transmits the data output command to the memory chip CP1 being a read target (S602).

After transmitting the data output command, the host HA transmits a data input command in the active state of the chip enable signal CEn #H3 (S603). The configuration of the data input command is identical to that of the first embodiment.

From the active state of the chip enable signal CEn #H3 upon reception of the data input command, the bridge chip BCa recognizes that the data input command is addressed to the memory chip CP3 connected to the channel #3. The bridge chip BCa transmits the data input command to the memory chip CP3 (S604).

After completion of transmitting the data input command, the host HA transmits write data in the active state of the chip enable signal CEn #H3 (S605). The host HA transmits the write data addressed to the memory chip CP3 as the data signal DQ[7:4]. The host HA transmits the data signal DQ[7:4] at the transfer frequency twice higher than the transfer frequency of the data signal DQ[7:0] in the NAND-side channel. In transmitting the write data, the host HA toggles the data strobe signal DQS/DQSn #H3.

From the active state of the chip enable signal CEn #H3 upon reception of the write data, the bridge chip BCa recognizes that the data is addressed to the memory chip CP3 connected to the channel #3. The bridge chip BCa converts the bit width of the write data from 4-bits to 8-bits and transmits the data as the data signal DQ #3[7:0] to the memory chip CP3 as a destination (S606). The transfer frequency of the data signal DQ #3[1:0] is set to half the transfer frequency of the data signal DQ[7:4].

After transmitting the write data, the host HA transmits the command value C3 for instructing as to start of a write operation, in the active state of chip enable signal CEn #H3 (S607).

From the active state of the chip enable signal CEn #H3 upon reception of the command value C3, the bridge chip BCa recognizes that the command value C3 is addressed to the memory chip CP3 connected to the channel #3. The bridge chip BCa transmits the command value C3 to the memory chip CP3 (S608).

In response to receipt of the command value C3, the memory chip CP3 controls its own word line to write the received write data.

After S607, the host HA starts toggling the read enable signal REn/RE #H1 in the active state of the chip enable signal CEn #H1 (S609). The host HA toggles the read enable signal REn/RE #H1 at the frequency twice higher than the read enable signal REn/RE transferred through the NAND-side channel.

From the active state of the chip enable signal CEn #H1 while the read enable signal REn/RE #H1 is being toggled, the bridge chip BCa recognizes that the toggling of the read enable signal REn/RE #H1 is targeted at the memory chip CP1 connected to the channel #1. The bridge chip BCa starts toggling the read enable signal REn/RE #1 in the channel CH1 (S610).

In response to the read enable signal REn/RE #1 being toggled, the target memory chip CP1 starts outputting read data (S611). To output the read data, the memory chip CP1 toggles the data strobe signal DQS/DQSn #1 at the same frequency as the read enable signal REn/RE #1 that the memory chip CP1 has received.

The bridge chip BCa receives the read data and converts the bit width of the read data from 8-bits to 4-bits to transmit the read data to the host HA (S612). The bridge chip BCa transmits the read data as the data signal DQ[3:0]. The bridge chip BCa transmits the data signal DQ[3:0] at the transfer frequency twice higher than the transfer frequency of the data signal DQ[7:0] in the NAND-side channel. To transmit the read data, the bridge chip BCa toggles the data strobe signal DQS/DQSn #H1.

Thus, it can be seen from FIG. 21 that the signal line for transferring the data signals DQ[7:0] in the host-side channel are split into two, and the data is transferred asynchronously in the two paths.

The above example has mainly described the operation with the transfer-rate scale factor 116 set to two. At the transfer-rate scale factor 116 being a natural number of three or more, in the host-side channel the data strobe signals DQS/DQSn and the read enable signals REn/RE can be controlled individually in the respective paths to transfer data asynchronously.

According to the first modification of the second embodiment, thus, the host-side channel includes the K sets of signal lines for transferring the control signals serving to control data transfers, i.e., the signal lines for transferring the data strobe signal DQS/DQSn and the signal lines for transferring the read enable signal REn/RE. N is smaller than K. The bridge chip BCa is configured to be able to asynchronously perform N streams of data transfer in the host-side channel by the control signals transferred in N of the K sets. A bit width of each stream is smaller than the bus width of the host-side channel.

Second Modification

A second modification of the second embodiment is different from the first modification in that the signal line for transferring the command-latch enable signal CLE, the signal line for transferring the address enable signal ALE, and the signal line for transferring the write enable signal WEn are multiplexed by K.

The command-latch enable signal CLE, the address-latch enable signal ALE, and the write enable signal WEn serve as control signals for controlling the transfer of commands and addresses in the signal lines in which the data signal DQ is transferred. By multiplexing the set of the signal lines for transferring the command-latch enable signal CLE, the address-latch enable signal ALE, and the write enable signal WEn, it is made possible to asynchronously transfer commands and addresses in the host-side channel through communication paths having a bit width smaller than the bus width of the host-side channel. That is, commands and addresses may not be transferred through the channels in a synchronous manner or different commands or addresses may be transferred in two different communication paths. That is, commands, addresses, and data can be asynchronously transferred through different communication paths.

Hereinafter, a memory system SYSa according to the second modification of the second embodiment will be described. The same or like elements of the memory system SYSa according to second modification of the second embodiment as those of the first modification will be briefly described, or a description thereof will be omitted.

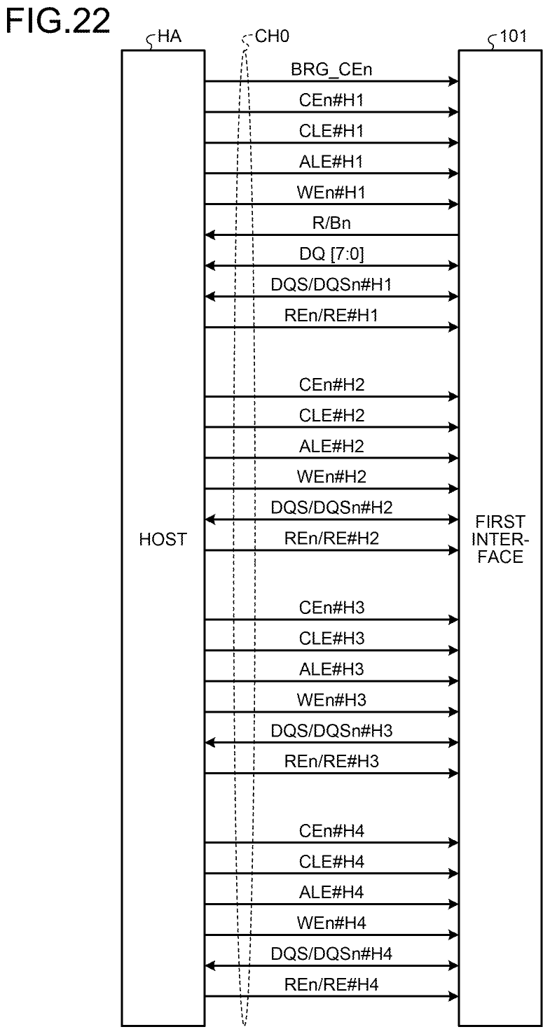

FIG. 22 is a schematic diagram illustrating a configuration of a host-side channel (i.e., channel CH0) according to second modification of the second embodiment. According to the second modification, the channel CH0 includes, for each NAND-side channel, a signal-line set including the signal line for transferring the chip enable signal CEn, the signal line for transferring the command-latch enable signal CLE, the signal line for transferring the address enable signal ALE, the signal line for transferring the write enable signal WEn, the signal lines for transferring the data strobe signal DQS/DQSn, and the signal lines for transferring the read enable signal REn/RE. The chip enable signal CEn, the command-latch enable signal CLE, the address enable signal ALE, the write enable signal WEn, the data strobe signal DQS/DQSn, and the read enable signal REn/RE transferred in a Z-th signal-line set will be referred to as a chip enable signal CEn #HZ, a command-latch enable signal CLE #HZ, an address enable signal ALE #HZ, a write enable signal WEn #HZ, a data strobe signal DQS/DQSn #HZ, and a read enable signal REn/RE #HZ where Z is a natural number of 1 to 4.

In the example illustrated in FIG. 22, both M and K are set to 4. As in the first modification, in the second modification K is a natural number of two or more and M or less. Also, a possible maximum value of N is K. The signal line for transferring the chip enable signal CEn included in the host-side channel may not be multiplexed.

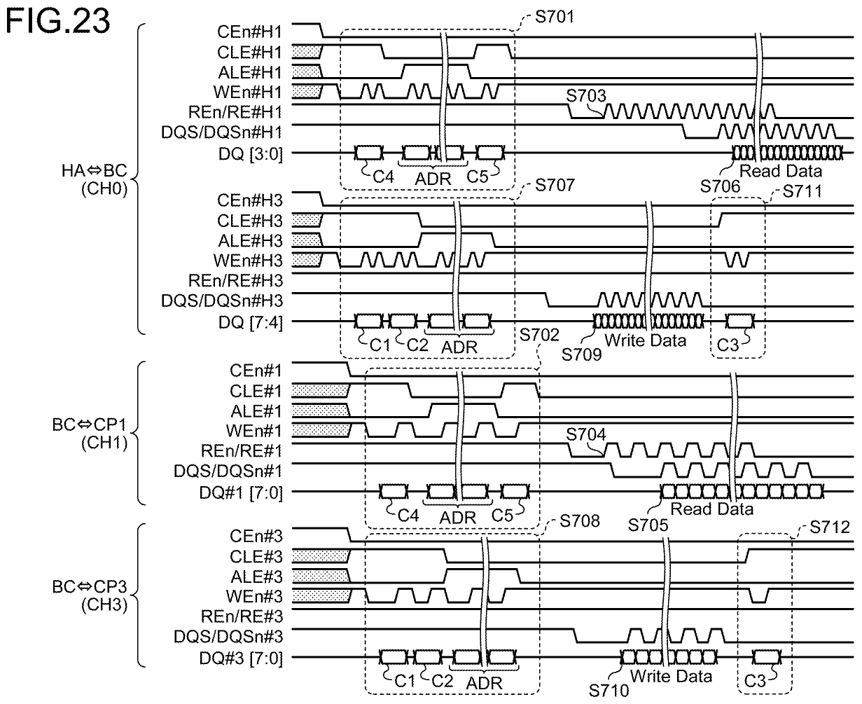

FIG. 23 is a timing chart illustrating various signal waveforms in an operation of the memory system SYSa according to the second modification of the second embodiment. In FIG. 23, the transfer-rate scale factor 116 is set to two, a memory chip CP1 connected to the channel CH1 is subjected to a read operation, and a memory chip CP3 connected to the channel CH3 is subjected to a write operation by way of example. A series of operations illustrated in FIG. 23 is performed while the bridge chip BCa is maintained in the non-bridge control mode. FIG. 23 omits illustrating the bridge chip enable signal BRG_CEn.

First, the host HA transmits a data output command in the active state of the chip enable signal CEn #H1 (S701). In S701 the host HA transmits a command value C4, an address ADR, and a command value C5 in this order as the data signal DQ[3:0]. In transmitting the command values C4 and C5, the host HA maintains the command-latch enable signal CLE #H1 in an active state (H-level) and toggles the write enable signal WEn #H1. In transmitting the address value ADR, the host HA maintains the address-latch enable signal ALE #H1 in an active state (H-level) and toggles the write enable signal WEn #H1.

In the first embodiment, the second embodiment, and the first modification of the second embodiment, the command values C4 and C5 and the address ADR are transferred through the channel CH0 at an 8-bit width. In the second modification of the second embodiment, the bit width of the command values C4 and C5 and the address ADR for transfer decreases depending on the transfer-rate scale factor 116. According to the example illustrated in FIG. 23, the transfer-rate scale factor 116 is set to two. Thus, the command values C4 and C5 and the address ADR are transferred through the channel CH0 at half the bit width in the first embodiment, the second embodiment, and the first modification of the second embodiment. That is, to transfer the command values C4 and C5 and the address ADR through the channel CH0, the command-latch enable signal CLE and the address-latch enable signal ALE are placed in a longer active (H-level) period, and the read enable signal REn/RE is toggled by a doubled number of times, as compared with the first embodiment, the second embodiment, and the first modification of the second embodiment.

The bridge chip BCa receives the data signal DQ[3:0] as a data output command, converts the bit width of the data output command from 4-bits to 8-bits. The bridge chip BCa transmits the data output command after conversion as the data signal DQ #1[1:0] to the memory chip CP1 being a read target (S702).

After transmitting the data output command, the host HA starts toggling the read enable signal REn/RE #H1 (S703). The host HA toggles the read enable signal REn/RE #H1 at the frequency twice higher than the read enable signal REn/RE transferred through the NAND-side channel.

In response to the read enable signal REn/RE #H1 being toggled, the bridge chip BCa starts toggling the read enable signal REn/RE #1 in the channel CH1 (S704).

In response to the read enable signal REn/RE #1 being toggled, the memory chip CP1 being a read target starts outputting read data (S705). To output the read data, the memory chip CP1 toggles the data strobe signal DQS/DQSn #1 at the same frequency as the read enable signal REn/RE #1 that the memory chip CP1 has received.

Upon receipt of the read data, the bridge chip BCa converts the bit width of the read data from 8-bits to 4-bits and transmits the read data to the host HA (S706). The bridge chip BCa transmits the read data as the data signal DQ[3:0]. The bridge chip BCa transmits the data signal DQ[3:0] at the transfer frequency twice higher than the transfer frequency of the data signal DQ[7:0] in the NAND-side channel. To transmit the read data, the bridge chip BCa toggles the data strobe signal DQS/DQSn #H1.

In parallel with S701, the host HA transmits the data input command (S707) in the active state of the chip enable signal CEn #H3. In S707 the host HA transmits the command values C1 and C2 and the address ADR in this order as the data signal DQ[7:4]. In transmitting the command values C1 and C2, the host HA maintains the command-latch enable signal CLE #H3 in an active state (H-level) and toggles the write enable signal WEn #H3. In transmitting the address value ADR, the host HA maintains the address-latch enable signal ALE #H3 in an active state (H-level) and toggles the write enable signal WEn #H3. Thus, as with the data output command, in transmitting the data input command, the command-latch enable signal CLE and the address-latch enable signal ALE are placed in a longer active (H-level) period, and the read enable signal REn/RE is toggled by a doubled number of times as compared with the first embodiment, the second embodiment, and the first modification of the second embodiment.

The bridge chip BCa receives the data signal DQ[7:4] being a data output command, converts the bit width of the data input command from 4-bits to 8-bits. The bridge chip BCa transmits the data signal DQ #3[7:0] being the data input command after conversion to the memory chip CP3 being a write target (S708).

After completion of transmitting the data input command, the host HA transmits write data in the active state of the chip enable signal CEn #H3 (S709). The host HA transmits the write data addressed to the memory chip CP3 as the data signal DQ[7:4]. The host HA transmits the data signal DQ[7:4] at the transfer frequency twice higher than the transfer frequency of the data signal DQ[7:0] in the NAND-side channel. In transmitting the write data, the host HA toggles the data strobe signal DQS/DQSn #H3.

The bridge chip BCa receives the data signal DQ[7:4] being the write data, converts the bit width of the write data from 4-bits to 8-bits and transmits the write data after conversion as the data signal DQ #3[7:0] to the memory chip CP3 being a write target (S710). The transfer frequency of the data signal DQ #3[1:0] is set to half the transfer frequency of the input data signal DQ[7:4].

After transmitting the write data, the host HA transmits the command value C3 for instructing as to start of a write operation, in the active state of the chip enable signal CEn #H3 (S711). In S711 the host HA transmits the data signal DQ[7:4] being the command value C3. In transmitting the command value C3, the host HA maintains the command-latch enable signal CLE #H3 in an active state (H-level) and toggles the write enable signal WEn #H3.

The bridge chip BCa receives the command value C3 as the data signal DQ[7:4], converts the command value C3 from a 4-bit width to an 8-bit width. The bridge chip BCa transmits the data signal DQ #3[7:0] being the command value C3 after conversion to the memory chip CP3 being a write target (S712).

The memory chip CP3 receives the command value C3 and controls its own word line to write the received write data.

As is seen from FIG. 23, the signal line for transferring the data signals DQ[7:0] in the host-side channel are split into two paths. Thereby, commands, addresses, and data are mutually independently and asynchronously transferred in the two paths.

The above example has mainly described the operation at the transfer-rate scale factor 116 of 2. At the transfer-rate scale factor 116 being a natural number of 3 or more, in the host-side channel, commands, addresses, and data can be asynchronously transferred in the respective paths by individually controlling the command-latch enable signal CLE, the address-latch enable signal ALE, the write enable signal WEn, the data strobe signal DQS/DQSn, and the read enable signal REn/RE in the respective paths.

According to the second modification of the second embodiment, thus, the host-side channel includes K sets of signal lines each of which includes the three signal lines for transferring the command-latch enable signal CLE, the address-latch enable signal ALE, and the write enable signal WEn serving as the control signals to control command and address transfer, and the two signal lines for transferring the data strobe signal DQS/DQSn and the read enable signal REn/RE serving as the controls signals to control data transfer. N is smaller than K. The bridge chip BCa is configured to be able to asynchronously perform N streams of data transfer each having a bit width smaller than the bus width of the host-side channel by the control signal being transferred respectively in N of the K signal-line sets for controlling command and address transfer and for controlling data transfer.

Third Modification

in the first modification of the second embodiment, commands and addresses are transferred in the host-side channel at the same bit width as the host-side channel. In the first modification of the second embodiment as in the second modification of the second embodiment, in the host-side channel, commands and addresses may be transferred via N communication paths having a bit width smaller than the bus width of the host-side channel.

However, in the first modification of the second embodiment, the three signal lines for transferring the command-latch enable signal CLE, the address-latch enable signal ALE, and the write enable signal WEn are included in common in the N communication paths. Thus, to overlap the command and address transmission periods in two or more communication paths in the host-side channel, the fact that commands and addresses cannot be asynchronously transmitted in two or more communication paths may be preferably taken into consideration.

Fourth Modification

In the second embodiment and the modifications of the second embodiment, the data signals DQ as commands and addresses are transferred. The commands and the addresses may be transferred through signal lines different from the signal lines through which the data signals DQ are transferred.

### Third Embodiment

The bridge chip is connected to the host-side channel and M NAND-side channels. Each of the channels includes a plurality of signal lines. The number of terminals included in the bridge chip increases depending on the number of the NAND-side channels.

In a third embodiment, the M NAND-side channels share some signal lines. This prevents an increase in the number of terminals included in the bridge chip.

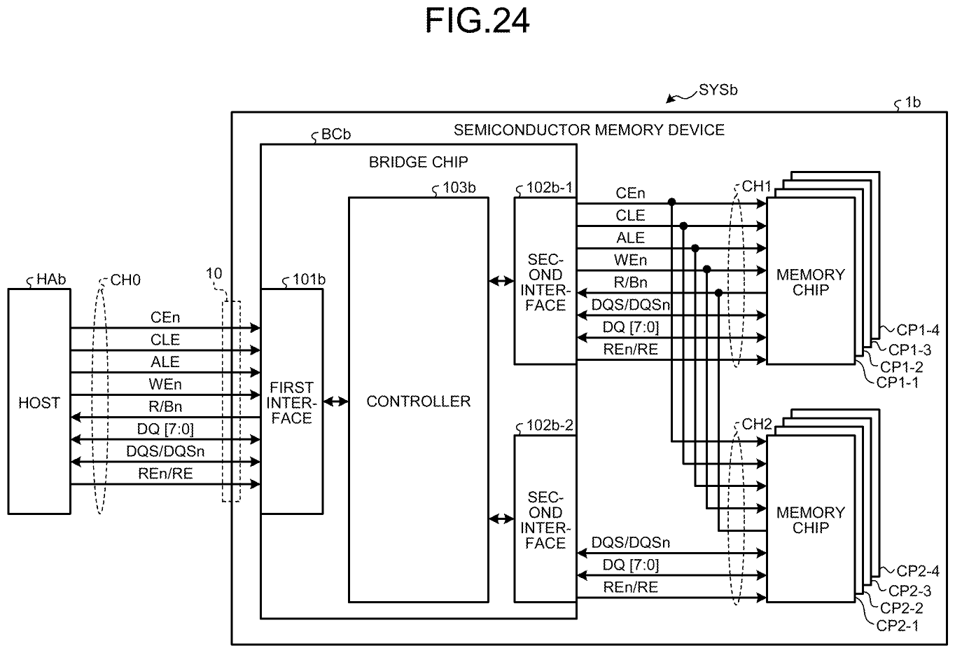

FIG. 24 is a schematic diagram illustrating an exemplary configuration of a memory system SYSb according to the third embodiment.

The memory system SYSb includes a host HA and a semiconductor memory device 1b. The semiconductor memory device 1b includes a bridge chip BCb and a plurality of memory chips CP. In the example illustrated in FIG. 24, the semiconductor memory device 1b includes eight memory chips CP.

The bridge chip BCb is electrically connected between an external terminal group 10 and M channels (herein, as an example, two channels CH1 and CH2). The external terminal group 10 is electrically connected to the host HA via the channel CH0.

Among the eight memory chips CP, the memory chips CP1-1 to CP1-4 are connected to the channel CH1 and the memory chips CP2-1 to CP2-4 are connected to the channel CH2.

The bridge chip BCb includes a first interface 101b, two second interfaces 102b, and a controller 103b.

The first interface 101b serves as a PHY circuit which transmits and receives electric signals to and from the host HA via the channel CH0.

Of the two second interfaces 102b, the second interface 102b-1 serves as a PRY circuit which transmits and receives electric signals to and from the four memory chips CP1 via the channel CH1. The second interface 102b-2 serves as a PHY circuit which transmits and receives electric signals to and from the four memory chips CP2 via the channel CH2.

The controller 103b is disposed between the first interface 101b and the two second interfaces 102b. The controller 103b serves to control signal reception and transmission between the first interface 101b and the two second interfaces 102b.

The two channels CH1 and CH2 being the NAND-side channels each include a signal line for transferring a chip enable signal CEn, a signal line for transferring a command-latch enable signal CLE, a signal line for transferring an address-latch enable signal ALE, a signal line for transferring a write enable signal WEn, a signal line for transferring a ready/busy signal R/Bn, signal lines for transferring a data signal DQ[7:0] having a given bus width (herein, for example, 8-bit width), signal lines for transferring a data strobe signal DQS/DQSn, and signal lines for transferring a read enable signal REn/RE.

One end of each of the signal line for transferring the chip enable signal CEn, the signal line for transferring the command-latch enable signal CLE, the signal line for transferring the address-latch enable signal ALE, the signal line for transferring the write enable signal WEn, and the signal line for transferring the ready/busy signal R/Bn is connected to the second interface 102b-1. The other end of each of the signal line for transferring the chip enable signal CEn, the signal line for transferring the command-latch enable signal CLE, the signal line for transferring the address-latch enable signal ALE, the signal line for transferring the write enable signal WEn, and the signal line for transferring the ready/busy signal R/Bn branches into eight signal lines, and are individually connected to the eight memory chips CP. Thereby, the channels CH1 and CH2 share the signal line for transferring the chip enable signal CEn, the signal line for transferring the command-latch enable signal CLE, the signal line for transferring the address-latch enable signal ALE, the signal line for transferring the write enable signal WEn, and the signal line for transferring the ready/busy signal R/Bn.

By configuring the channels CH1 and CH2 as above, the bridge chip BCb can decrease in the number of terminals connected to the signal lines for transferring the chip enable signal CEn, the command-latch enable signal CLE, the address-latch enable signal ALE, the write enable signal WEn, and the ready/busy signal R/Bn.

The third embodiment has described the example that the semiconductor memory device 1b includes the two NAND-side channels and the two NAND-side channels share part of the signal lines. The semiconductor memory device 1b may include three or more NAND-side channels. In such a case at least two of the NAND-side channels can share part of the signal lines.

In the third embodiment, particularly, the NAND-side channels share the signal lines for transferring the control signals (command-latch enable signal CLE, address-latch enable signal ALE, and write enable signal WEn) serving to control transfers of commands and addresses. The configuration of the NAND-side channels sharing the signal lines for transferring the control signals serving to control commands and address transfers is applicable to both of the first embodiment and the second embodiment.

According to the third embodiment as described above, at least two NAND-side channels can share the signal lines for transferring the control signals (command-latch enable signal CLE, address-latch enable signal ALE, and write enable signal WEn) serving to control command and address transfers.

This makes it possible to prevent an increase in the number of terminals included in the bridge chip BCb.

While certain embodiments have been described, these embodiments have been presented by way of example only, and are not intended to limit the scope of the inventions. Indeed, the novel methods and systems described herein may be embodied in different other forms; furthermore, various omissions, substitutions and varies in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of first chips; and
a second chip connectable to a host via a first channel and connected to the plurality of first chips via M second channels where M is a natural number of two or more, the second chip is configured to:
in response to receipt of first data via the first channel at a transfer rate N times higher than a transfer rate per a single second channel where N is a natural number of two or more and M or less, sort the first data into N pieces in a unit of a bus width of the first channel to split the first data into N pieces of second data, and transmit the N pieces of second data to N of the plurality of first chips corresponding to N of the M second channels in parallel via the N second channels; and
in response to receipt of L pieces of third data in parallel from L of the M second channels where L is a natural number of two or more and M or less, generate a single piece of fourth data by concatenating the L pieces of third data in the unit of the bus width of the first channel, and transmit the fourth data via the first channel at a transfer rate L times higher than a transfer rate per the single second channel.

2. The semiconductor memory device according to claim 1, wherein
the second chip receives a set value of the N from the host.

3. The semiconductor memory device according to claim 1, wherein
the M second channels each includes:
a first signal line through which data is transferred, and
a second signal line group through which a first control signal is transferred, the first control signal serving to control data transfer in the first signal line; and
at least two of the M second channels share the second signal line group.

4. A semiconductor memory device comprising:
a plurality of first chips; and
a second chip connectable to a host via a first channel and connected to the plurality of first chips via M second channels where M is a natural number of two or more, the second chip is configured to:
in response to receipt of first data via the first channel at a transfer rate N times higher than a transfer rate per a single second channel where N is a natural number of two or more and M or less, split the first data into N pieces of second data by splitting the first data into data being smaller in bit width than a bus width of the first channel in a unit of the bus width of the first channel, convert the bit width of each of the N pieces of second data to the same width as a bus width of each second channel, and transmit the N pieces of second data to N of the plurality of first chips corresponding to N of the M second channels in parallel via the N second channels; and
in response to receipt of L pieces of third data in parallel from L of the M second channels where L is a natural number of two or more and M or less, convert a bit width of each of the L pieces of third data to a bit width smaller than the bus width of the first channel, and transmit fourth data via the first channel at a transfer rate L times higher than the transfer rate of the single second channel, the fourth data being the L pieces of third data concatenated in a direction of the bit width.

5. The semiconductor memory device according to claim 4, wherein
the second chip receives a set value of the N from the host.

6. The semiconductor memory device according to claim 5, wherein
the first channel includes:
a first signal line through which data is transferred, and
K second signal line groups through which first control signals are individually transferred, the first control signal serving to control data transfer in the first signal line;
the N and the L are settable to a value being the K or less;
the bus width of the first channel corresponds to the bus width of the first signal line; and
the second chip is configured to be able to asynchronously perform N or L streams of data transfer each in a bit width smaller than the bus width of the first signal line by the first control signals transferred in N or L of the K second signal line groups.

7. The semiconductor memory device according to claim 5, wherein
a first signal line through which data, a command, and an address are transferred,
K second signal line groups where K is a natural number of two or more and M or less, the K second signal line groups through which first control signals are individually transferred, the first control signals serving to control data transfer in the first signal line, and
K third signal line groups through which second control signals are individually transferred, the second control signals serving to control command and address transfer in the first signal line;
the N and the L are settable to a value of the K or less;
the bus width of the first channel corresponds to the bus width of the first signal line; and
the second chip is configured to be able to:
asynchronously perform N or L streams of data transfer each in a bit width smaller than the bus width of the first signal line through N or L of the K second signal line groups by the first control signals transferred in N or L of the K second signal line groups, and
asynchronously perform N or L streams of transfer of data, a command, and an address each in the bit width smaller than the bus width of the first signal line through N or L of the K second signal line groups by the first control signals transferred in N or L of the K second signal line groups and the second control signals transferred in N or L of the K third signal line groups.

8. The semiconductor memory device according to claim 4, wherein
the first channel includes:
a first signal line through which data is transferred, and
K second signal line groups where K is a natural number of two or more and M or less, the K second signal line groups through which first control signals are individually transferred, the first control signal serving to control data transfer in the first signal line;
the N and the L are settable to a value being the K or less;
the bus width of the first channel corresponds to the bus width of the first signal line; and
the second chip is configured to be able to asynchronously perform N or L streams of data transfer each in a bit width smaller than the bus width of the first signal line by the first control signals transferred in N or L of the K second signal line groups.

9. The semiconductor memory device according to claim 4, wherein
the first channel includes:
a first signal line through which data, a command, and an address are transferred,
K second signal line groups where K is a natural number of two or more and M or less, the K second signal line groups through which first control signals are individually transferred, the first control signals serving to control data transfer in the first signal line, and
K third signal line groups through which second control signals are individually transferred, the second control signals serving to control command and address transfer in the first signal line;
the N and the L are settable to a value of the K or less;
the bus width of the first channel corresponds to the bus width of the first signal line; and
the second chip is configured to be able to:
asynchronously perform N or L streams of data transfer each in a bit width smaller than the bus width of the first signal line through N or L of the K second signal line groups by the first control signals transferred in N or L of the K second signal line groups, and
asynchronously perform N or L streams of transfer of data, a command, and an address each in the bit width smaller than the bus width of the first signal line through N or L of the K second signal line groups by the first control signals transferred in N or L of the K second signal line groups and the second control signals transferred in N or L of the K third signal line groups.

10. The semiconductor memory device according to claim 4, wherein
the M second channels each includes:
a first signal line through which data is transferred, and
a second signal line group through which a first control signal is transferred, the first control signal serving to control data transfer in the first signal line; and
at least two of the M second channels share the second signal line group.

11. A memory system comprising:
the semiconductor memory device according to claim 1, and
the host connected to the semiconductor memory device.

12. A memory system comprising:
the semiconductor memory device according to claim 2, and
the host connected to the semiconductor memory device.

13. A memory system comprising:
the semiconductor memory device according to claim 3, and
the host connected to the semiconductor memory device.

14. A memory system comprising:
the semiconductor memory device according to claim 4, and
the host connected to the semiconductor memory device.

15. A memory system comprising:
the semiconductor memory device according to claim 5, and
the host connected to the semiconductor memory device.

16. A memory system comprising
the semiconductor memory device according to claim 6, and
the host connected to the semiconductor memory device.

17. A memory system comprising:
the semiconductor memory device according to claim 7, and
the host connected to the semiconductor memory device.

18. A memory system comprising:
the semiconductor memory device according to claim 8, and
the host connected to the semiconductor memory device.

19. A memory system comprising:
the semiconductor memory device according to claim 9, and
the host connected to the semiconductor memory device.

20. A memory system comprising:
the semiconductor memory device according to claim 10, and
the host connected to the semiconductor memory device.
